(19) United States
(12) Patent Application Publication
(10) Pub. No.: US 2026/0342290 A1
(43) Pub. Date: Oct. 29, 2026

(54) DIGITAL OPAMP: METHOD AND APPARATUS OF A STABILIZED NEGATIVE FEEDBACK SYSTEM

(71) Applicant: Thomas Christopher Rae, Irwin, PA (US)

(72) Inventor: Thomas Christopher Rae, Irwin, PA (US)

(21) Appl. No.: 19/630,885

(22) Filed: Mar. 27, 2026

Related U.S. Application Data
(63) Continuation of application No. PCT/US2025/010017, filed on Jan. 2, 2025.
(60) Provisional application No. 63/616,991, filed on Jan. 2, 2024.

(51) Int. Cl. H03F 1/34; H03F 3/189; H03F 3/45

(52) U.S. Cl. CPC H03F 1/34; H03F 3/189; H03F 3/45; H03F 2200/165

(57) ABSTRACT

Embodiments relate to a negative feedback amplifier circuit or system, and in particular a circuit topology for a amplifier circuit configured to add a signal to an inverted time-delayed version of itself to produce a clean low magnitude bandwidth limited derivative signal of the input. This low magnitude bandwidth limited derivative signal may be easily amplified and used to produce filtered signals without time delay with respect to the input. A zero-phase signal produced by the amplifier circuit may be calculated in real time using only the present signal and a time-delayed sample. A clean derivative of the input signal is produced which possesses negative group delay to drive a filter to generate a large gain signal with no delay with respect to the input signal and a wide bandwidth with flat response.

### TECHNICAL FIELD

The subject matter relates to an electrical signal processing. The subject matter may relate to a topology for a negative feedback amplifier. The topology may simultaneously function as a one or more of a hybrid opamp, sigma-delta Modulator with adjustable filter order, a single-bit Proportional-Integral-Derivative (PID) controller that is easily tune-able to a stable state and has true anticipatory control, a high flat gain linear phase wide-bandwidth class D amplifier with good power supply rejection ratio, etc. The subject matter may relate to a negative feedback amplifier circuit. The subject matter may relate to an amplifier circuit configured to simultaneously amplify and demodulate radio frequency (RF) signals.

### BRIEF DESCRIPTION OF THE DRAWINGS

The accompanying drawings are incorporated in and constitute part of the specification and illustrate various embodiments. In the drawings:

FIG. 1 illustrates an exemplary free running signal processing circuit topology adapted as an amplifier circuit;

FIG. 2 illustrates a near-minimal circuit topology for an embodiment of the amplifier circuit using an inverter;

FIG. 3 illustrates a near-minimal circuit topology for an embodiment of the amplifier circuit using a clocked flip-flop topology;

FIG. 4 illustrates an exemplary free running circuit topology for an embodiment of the amplifier circuit showing the circuit topology mathematically;

FIG. 5 illustrates an exemplary circuit topology for an embodiment of the amplifier circuit shown in FIG. 1 with specific components and component values;

FIGS. 6A-6B illustrate exemplary free running circuit topologies for an embodiment of the amplifier circuit shown in FIG. 1 with specific components and component values and designed to maintain an ‘inverted pendulum’ in inverted position;

FIG. 7 illustrates an exemplary free running circuit topology for an embodiment of the amplifier circuit which may offer an enhancement over a circuit topology of FIG. 1;

FIGS. 8A-8B illustrate a graph and an exemplary free running circuit topology for an embodiment of the amplifier circuit of FIG. 1 with reduced components;

FIGS. 9A-9B illustrates illustrate a graph and an exemplary free running circuit topology for an embodiment of the amplifier circuit shown in FIG. 1 with another set of specific components and component values;

FIGS. 10A-10C illustrate how a derivative of a signal may be created (calculated) by subtracting a delayed signal from its original source signal;

FIGS. 11A-11B illustrate a graph and a specific version of FIG. 3 circuit with specific component values simulated and implementing MOSFETs with results derived;

FIGS. 12A-12B illustrate a graph and another specific version of FIG. 3 circuit with specific component values simulated and implementing Bipolar Transistors with results derived;

FIGS. 13A-13B illustrate a graph another specific version of FIG. 3 circuit with specific component values simulated and implementing Bipolar Transistors with results derived;

FIGS. 14A-14B illustrate a graph another specific version of FIG. 3 circuit with specific component values simulated and implementing Bipolar Transistors with results derived;

FIGS. 15A-15B illustrate a graph another specific version of FIG. 3 circuit with specific component values simulated and implementing Bipolar Transistors with results derived;

FIG. 16 illustrates a conceptual drawing of Proportional, Integral, and Derivative elements which may arise from the circuit shown;

FIG. 17 illustrates an exemplary free running circuit topology for an embodiment of the amplifier circuit shown in FIG. 1 with specific components and component values and designed to create a specific voltage gain and current gain;

FIGS. 18A-18B illustrate a graph an exemplary free running circuit topology for an embodiment of the amplifier circuit shown in FIG. 1 with specific components and component values and designed to create a different specific voltage gain and different current gain;

FIGS. 19A-19B illustrate a graph an exemplary free running circuit topology for an embodiment of the amplifier circuit shown in FIG. 1 with specific components and component values and designed to create a different specific voltage gain and different current gain;

FIGS. 20A-20B illustrate a graph an exemplary free running circuit topology for an embodiment of the amplifier circuit shown in FIG. 1 with specific components and component values and designed to create a different specific voltage gain and different current gain;

FIG. 21 illustrates a graph showing the output of an embodiment of the amplifier circuit approaching matching of the input as the high frequency loop gain is increased;

FIG. 22 illustrates a graph showing the increasing frequency response of bandwidth of the signals in FIG. 21;

FIG. 23 illustrates a point where the high frequency gain is too large and the noise starts to increase;

FIG. 24 illustrates an overview of the many of the circuits detailed herein;

FIG. 25 illustrates FIG. 1 but detailing and naming the specific interconnect nodes;

FIG. 26 illustrates the derivative created V(stage_1) to drive the second amplifier and create an output V(stage_2) that matches the input−V(in) without delay for the circuit in FIG. 7;

FIGS. 27A-27B illustrate a graph and a component circuit using principles embodied in the circuit of FIG. 1;

FIG. 28A illustrates diagram of a signal processing topology;

FIG. 28B illustrates an addition function that may be employed within the signal processing topology of FIG. 28A;

FIG. 29 illustrates an inverting amplifier circuit;

FIG. 30 illustrates a PID controller using an inverting amplifier.

### DETAILED DESCRIPTION

The following description is of exemplary embodiments that are presently contemplated for carrying out the present subject matter. This description is not to be taken in a limiting sense, but is made merely for the purpose of describing the general principles and features of various aspects of the subject matter.

Various circuits, or other components may be described or claimed as “configured to” perform a task or tasks. In such contexts, “configured to” or “operable for” is used to connote structure by indicating that the circuits include structure (e.g., components) that performs the task or tasks during operation. As such, the circuit can be said to be configured to (or be operable) for perform(ing) the task even when the specified circuit is not currently operational (e.g., is not on). The circuits used with the “configured to” or “operable for” language include hardware-for example, electronics, circuit components, memory storing program instructions executable to implement the operation, etc. Reciting that a circuit is “configured to” or “operable for” perform(ing) one or more tasks is expressly intended not to invoke 35 U.S.C. .sctn.112, sixth paragraph, for that circuit. “Configured to” may also include adapting a manufacturing process to fabricate devices or components that are adapted to implement or perform one or more tasks.

Before elucidating the subject matter shown in the Figures, the present disclosure will be first described in general terms.

Noise filtering technology may include multiple time-delayed feedback terms in order to accomplish anticipatory coupling, which leads to a negative group delay for frequencies in the baseband. Signal prediction in noise filtering technology may be generally based on a prior analysis of the signal to be predicted, and then a subsequent model fit. The fitting procedure may be off-line, such as in some neural network approaches, which use a learning and a test data set, or in real time, such as in adaptive filtering. It may be advantageous for many applications if the modeling step could be omitted, which may result in a universal predictor. A universal predictor of a signal may be understood to be a predictor that does not depend on an underlying model of the signal. A solution to the universal prediction problem may be applicable for a wide class of signals generated by deterministic or stochastic systems. It is based on an amplifier with a negative group delay, which shifts signal components backwards in time, thus enabling prediction.

Embodiments may relate to an amplifier circuit, and in particular a circuit design or topology for an amplifier circuit. Embodiments of the amplifier circuit may generate a negative group delay by forcing the filtered output of a square wave oscillator to match the input. For instance, the amplifier circuit may force the output to match the input by subtracting the output from the input and quantizing the error which is a clean derivative of the input signal. A bitstream may be created with the square wave oscillator carrier frequency and the derivative of the input signal modulated in its bit width. The bitstream is filtered with a simple resistor-capacitor (RC) amplifier and negatively fed back to the summing node which serves as a virtual ground and represents the error signal.

The amplifier circuit configured to process an electrical signal, may at least reduce if not eliminate large oscillating errors. In the amplifier stabilization circuit, a second resistive feedback path causes the carrier wave frequency and the derivative of the input signal to be negatively fed back, thereby lowering the high frequency gain. If used for sigma-delta modulation, the lower high frequency gain results in lowering the order of the sigma-delta modulation. This may cause a system utilizing the amplifier circuit to converge quickly with great stability, providing a bitstream with an amplified derivative of the input signal and a filtered bitstream that matches the input signal without filter delay. The switching frequency of the bitstream is greatly increased and the deviations from the setpoint (error) is minimized, creating a much smoother waveform. In addition, the derivative signal of the input is a perfectly pre-emphasized signal, such that, after a resister-capacitor (RC) amplifier, the carrier is removed and the output signal remains which theoretically matches the input signal exactly without delay.

With the amplifier circuit, the bitstream may contain a pre-emphasized version of the input signal to compensate for the delay caused by the filtering function of the circuit. Thus, the amplifier circuit may actively and dynamically create the negative group delay signal necessary to cancel the experienced delay of the circuit. With the amplifier circuit, the input signal modulates the pulse width of the square wave oscillator and may tolerate delays in the digital stream while actively compensating for delays in the input signal. This allows control loops within a system utilizing the amplifier circuit to operate at higher loop rates. Using the anticipatory action of the negative group delay to compensate for delays results in improved performance.

While the amplifier circuit may be used for various functions and employed for several practical applications, it should be noted that it is particularly well suited for system noise cancellation. In this regard, and as will be demonstrated herein, the amplifier circuit may outperform complex computer systems configured to calculate state space equations to cancel noise. The universality of the amplifier circuit as a noise filtering circuit may be attributed to it not relying on a specific model of the signal e.g., as long as the signal to be predicted is band-limited with a known cutoff frequency, the amplifier may predict the signal in real time up to a prediction horizon that depends on the cutoff frequency. The amplifier circuit acts as a single-bit processor dedicated to nothing else but minimizing the error by creating the signal needed to cancel the error.

As another exemplary use, the amplifier circuit may be configured as an ultra-efficient wideband motor controller to provide three control loops of a motor controller—e.g., provide triple derivative action for jerk control of motor motion.

As another exemplary use, the amplifier circuit may be configured to switch at a desired tuning frequency so as to simultaneously amplify and demodulate a signal of a RF modulated signal.

The amplifier circuit may be or be associated with a hardware circuit, a software circuit module, or a combination of both. The circuit may be a circuit built on a substrate, built on a printed circuit board, etc. The circuit may be part of, associated with, or included in or on at least one processor. A non-transitory machine-readable storage medium may be provided and may include instructions that when executed by one or more processors cause the at least one processor to perform functions in accordance with the circuit topology and methods disclosed herein. The at least one processor may be part of or in communication with a machine (logic, one or more components, circuits (e.g., modules), or mechanisms).

The at least one processor may be hardware (e.g., processor, integrated circuit, central processing unit, microprocessor, core processor, computer device, etc.), firmware, software, etc. configured to perform operations by execution of instructions embodied in algorithms, data processing program logic, artificial intelligence programming, automated reasoning programming, etc. The at least one processor may include one or more processing modules. A processing module may be a software or firmware operating module configured to implement any of the method steps disclosed herein or perform functions in accordance with the circuit topology disclosed herein. The processing module may be embodied as software and stored in memory, the memory being operatively associated with the processor.

The at least one processor may include or be associated with a computer or non-transitory machine readable medium. The computer or non-transitory machine readable medium may include memory. The memory may be computer readable memory configured to store data. The memory may include a volatile or non-volatile, transitory or non-transitory memory, and be embodied as an in-memory, an active memory, a cloud memory, etc. Embodiments of the memory may include a processor module and other circuitry to allow for the transfer of data to and from the memory, which may include to and from other components of a device, system, etc. This transfer may be via hardwire or wireless transmission. The device or system may include transceivers, which may be used in combination with switches, receivers, transmitters, routers, gateways, wave-guides, etc. to facilitate communications via a communication approach or protocol for controlled and coordinated signal transmission and processing to any other component or combination of components of the device or system. The transmission may be via a communication link. The communication link may be electronic-based, optical-based, opto-electronic-based, quantum-based, etc.

The computer or non-transitory machine readable medium may be configured to store one or more instructions thereon. The instructions may be in the form of algorithms, program logic, etc. that cause the processor to carry out the functions disclosed herein.

The at least one processor may be in communication with other processors of other devices. Any of those other devices may include any of the exemplary processors disclosed herein. Any of the processors may have transceivers or other communication devices/circuitry to facilitate transmission and reception of wireless signals. Any of the processors may include an Application Programming Interface (API) as a software intermediary that allows two applications to talk to each other. Use of an API may allow software of the processor to communicate with software of the processor of the other device(s).

An amplifier circuit topology subtracts a time-delayed signal from the original to produce (generate) a derivative of the signal. This derivative is then amplified and applied to an amplifier. By controlling the gain of this derivative, a very stable system may be produced.

Another way to conceptualize the subject matter more generally disclosed herein for some individuals of specific ordinary skill set in the art is as follows:

The system can converge with the feedback resistance being infinite and the all pass gain being infinite. The summing node capacitor function is to route the square wave odd harmonics currents to ground. The difference signal is still there creating the calculated derivative, the derivative voltage on the inductor is integrated and the current now matches the input current. The current is dropped across the resistor for feedback. This system converges, one because it is nearly ideal. But it has a small range of convergence. As soon as the real world component characteristics are considered the system stops converging. If the derivative magnitude is low from using a high frequency clock, the resistor may not be needed, the magnitude of the calculated derivative used in the system can be lowered by using a faster clock and possibly allow convergence without the all-pass feedback resistor.

When this topology stops converging it is caused by the derivative gain being too high (infinite) adding the resistor and lowering the gain will bring the system back into convergence. When two feedback resistors approach being equal, the high frequency loop starts to dominate and the system converges with the output being filtered as expected from an RC filter. The optimal condition is when the two feedback resistors are 100:1 to 1000:1

Most systems will stop converging when the all-pass feedback resistor is too high.

Also, there is no signal prediction happening in this invention. The derivative is a calculated derivative. y(t)=x(t)−delay(x(t), 10 ns) and y(t)=dx(t)/dt magnitude proportional to the delay.

The feedback mechanism may be configured with one low frequency bandwidth limited feedback and one high frequency feedback. The low frequency current typically being about 100 times the high frequency current for optimal convergence. The low frequency current dominates and is stabilized by the high frequency current.

If the high frequency current is made equal to the low frequency current. Convergence most always occurs due to high frequency dominating and the output is attenuated by the full effect of the filter.

As the high frequency current decreases by increasing the resistor value, the system compensates for the filter by applying a larger derivative on the RC filter. This improves until the output is nearly identical to the input with an almost zero time delay. Increasing the resistance further causes the system to loose tight regulation and gets significantly noisier. Although it is still converging, but with much less desirable characteristics.

A calculated derivative has 90 degree lead on the signal and this is the limit. This 90 degree lead is used to compensate for the 90 lag of the RC filter.

A linear inverting amplifier may be used in many applications. An inverting amplifier, such as the design found in a logic inverter may improves sensitivity. An inverting amplifier may be a linear inverting amplifier. An inverting amplifier may be a digital logic inverter. The logic inverter may improve sensitivity of signal processing. An inverting amplifier may be provided with a hysteresis. An inverting amplifier may be provided without the hysteresis. An inverting amplifier may be provided with a hysteresis. An inverting amplifier may be provided with a threshold of ½ Vcc. The circuit may be powered with both positive and negative voltage rails with a threshold at ground level. Preferably, the amplifier will have minimal or no hysteresis.

The amplifier circuit may be designed to oscillate no higher than the switching frequency and all of the analog paths have capacitors to ground and are therefore low pass filtered, Making the circuit highly stable and robust.

In the amplifier circuit, the input signal is amplified, inverted and sent through the process and summed with the inverse of itself.

A converging feedback systems may create a derivative of the input control signal by subtracting a delayed control signal from itself. The amplifying topology compensates for this derivative, balancing the system and creating a basic building block amplifier.

The derivative created may negative group delay. This negative delay is used to produce an equal and opposite near duplicate of the input signal. The generated derivative may be a bandwidth limited derivative. The derivative may be calculated but not predicted. The derivative may be calculated by these equations:

y(t)=x(t)−delay(x(t), 10 ns)

y(t)=dx(t)/dt magnitude proportional to the delay.

A negative group delay (NGD) in certain conditions, especially with bandwidth-limited signals, may enable the group delay to appear negative. This might seem counterintuitive, as it implies a signal's peak output appears to precede its peak input. This doesn't violate causality, though; it's a result of the way signals are processed and can be observed in specific engineered systems like certain types of filters.

A convergence in a negative feedback amplifier refers to the process by which the amplifier dynamically adjusts its output to achieve a stable and accurate representation of the input signal. This adjustment may be driven by a feedback mechanism that continuously compares the output signal to the input signal, generating an error signal. The amplifier then reduces this error signal over successive iterations, thereby minimizing deviations and enhancing performance.

Convergence of the system may be defined as the summation node being a steady voltage. Deviation from this steady voltage may indicate non-convergence.

A discreet version of the amplifier topology is the simulation illustrates the system converging in analog and digital mode. Analog mode has no switching action, but still amplifies and illustrates a derivative at the summation point.

The logic element may take the small voltage at the summation node and encodes the signal into the time domain. This sigma delta square waVe contains a derivative of the input signal encoded into the timing of the square wave. This sigma delta square wave which is applied to the RC filter reintegrates the derivative signal to produce a voltage matching the input and a current equal and opposite to the current flowing in the input resistor flows through the low frequency feedback resistor. The ratio of the two resistors determines the voltage gain at the output. If resistors are equal, the voltage gain is one.

Voltage gain (Vout/Vin) may be calculated as follows

Gain=(R_lp∥R_ap)/R_in

When R_ap>>R_lp

Gain=R_lp/R_in
and where,
   lp is a low pass,
   ap is an all pass
   in is an input

The value of the summing node voltage is the threshold voltage of the compare function.

The summation node can be monitored as an indicator of convergence.

A capacitor may be provided in the low pass filter in series with the input resistor to allow the summing node to float to the threshold voltage of the real world device used. It will be the voltage that the inverter or flip flop changes state. It is the virtual ground of the signal, 0 volt reference. The capacitor may be needed for inverter or flip flop to converge, because the switching point is not perfectly in the center of the dc supply voltage.

A square WAVE can be applied at any desired voltage level to achieve the power gain needed. The signal encoded in the time domain will scale.

The electrical signal to be processed may be a sampled signal.

A virtual ground node may be mathematically calculated by summing the input and the feedback currents. At each clock cycle a decision is made as to whether the input is above or below the output. This controls the switched mode voltage which produces the feedback currents.

The input signal may be amplified, inverted and sent through the process and summed with itself. It can never converge to absolute zero. There will always be a derivative of the input signal proportional to the delay of the feedback signal.

Converging feedback systems create a derivative of the input control signal by subtracting a delayed control signal from itself. This invention is the amplifier topology method and apparatus that compensates for this derivative, balancing the system and creating a basic building block amplifier with extraordinary characteristics.

The system (topology circuit, method) creates (generates, calculates, establishes, etc) the derivative of the input signal when the system converges, caused by subtracting a delayed version of the signal from itself. It appears at the summation point and gets amplified.

The subject matter calculates a derivative of an input signal, inherent to a converging feedback loop, and then compensates for such compensated for such derivative.

The subject matter also provides a negative feedback system topology that compensates for a derivative of a converging negative feedback system.

In view of the above, a method may produce bandwidth limited derivative that is much cleaner and easier to use. A fourth derivative of an input signal may be produced. This produces extremely large numbers when using regular math. Using the subtraction method, the second derivative would not be recognizable due to noise.

A control loop may be used to set a set point. The input is the desired set point. When the output matches the input, the first summation would be zero.

More generally, yet another way to consider the subject matter described herein is: an input-signal inverting amplification circuit comprising an input signal at an input terminal and also an output terminal outputting an inverted amplified signal, with an inverting amplifier circuit configured to execute an inverting amplification operation based on an input signal and to output a signal to the output terminal; wherein a delay circuit is connected at the output terminal of the inverting amplifier circuit, the input of the delay circuit being connected to the output terminal of the inverting amplifier, and wherein an output attenuation component is used, wherein the input of the attenuation component is connected to the output of the delay mechanism, and wherein an addition function having an input and an output, adds the input signal to the output of the attenuation component thereby outputting the sum of the input, the attenuated delayed inverted output, and the attenuated non-delayed output of the inverting amplifier; wherein a resulting signal amplification occurs and wherein said output attenuation component determines gain of amplification circuit.

In this circuit, the delay mechanism may comprise a low pass filter circuit and the low pass filter circuit may further comprise a resistor and a capacitor. In this circuit, the attenuation component may further comprise a resistor.

In this circuit, the addition function may further comprise: a common connection point between input signal, the output of the attenuation component, and a connection to the input the inverting amplifier.

In this circuit, the addition function may further comprise a low pass filter connected to its output.

In this circuit, the low pass filter may comprise a capacitor.

In this circuit, the circuit may further comprising an attenuation component between the input signal and the addition function.

In this circuit, the attenuation component may further comprise an input resistor. in this circuit, the circuit may further comprise a resistor between the output terminal of the inverting amplifier circuit and the input to the addition function.

In this circuit, the circuit may generate a useful amplified inverted output signal at the output of the delay mechanism.

In this circuit, the amplification circuit may further comprise a isolation means between the amplification circuit and the output signal and this isolation means may further comprise a capacitor.

In this circuit, the amplification may further comprise an isolation means between the input signal and the amplification circuit and the isolation means may further comprise a capacitor.

The amplifier circuit topology may be advantageous over conventional control loop circuitry, amplifier circuitry, and modulator circuitry suffer from the following deficiencies. Sigma Delta modulators circuits of 2^{nd}, 3^{rd}, or and higher orders may suffer from idle tones, harmonic distortions, noise modulations, dead zones, and stability issues. In addition, these devices may be complex and expensive. Conventional PID loops may be limited to unipolar operation schemes, may be difficult to tune, experience issues with integral windup, overshoot from disturbances, experience issues related to dead band and setpoint step change, etc. In addition, with conventional devices and methods, effective and efficient use of derivatives in control loops tends to be difficult due to high noise in the calculated derivative causing instability. Class D amplifiers may have issues with dead time and power supply rejection ratio. Bang-Bang or Hysteresis controllers may provide feedback control functionality, but their design causes them to exhibit large oscillating errors. The Bang-Bang or Hysteresis controller's high frequency gain may be too high, causing instability and wide deviations from the desired setpoint (error).

The signal processing topology (circuit, method) may generate a high gain wide bandwidth amplification on a single stage.

The signal processing topology (circuit, method) may be configured with a sigma delta encoding.

The signal processing topology (circuit, method) may provide a true PID anticipatory action.

The signal processing topology (circuit, method) may provide a class d amplification with power supply noise rejection.

The signal processing topology (circuit, method) may provide a RF modulation and demodulation.

Now in a reference to the drawings.

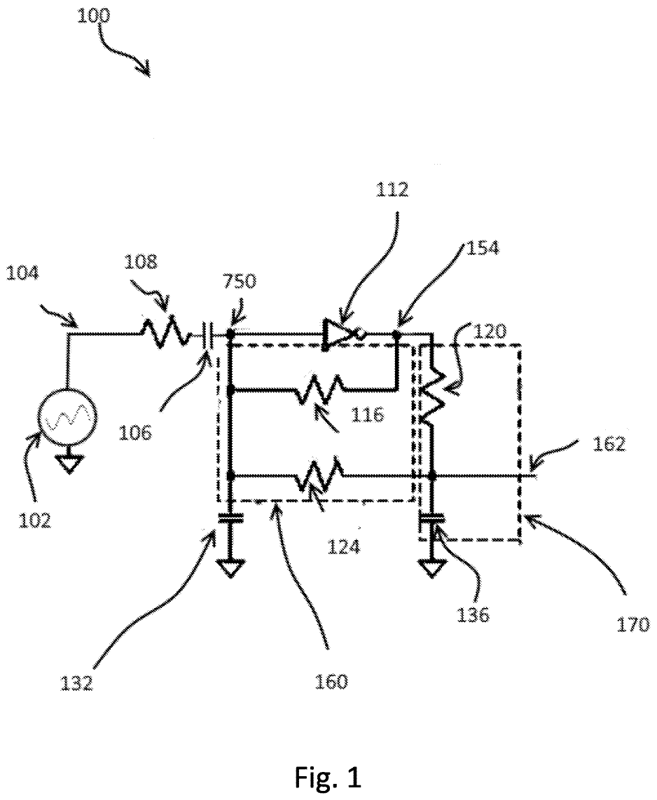

FIG. 1 illustrates an exemplary circuit topology for an embodiment of the inverting amplifier circuit.

Referring to FIG. 1, the inverting amplifier circuit 100 includes a 1.0 Kohm R3 resistor 108 which is configured to receive input (e.g., an input signal) 102. The input signal is an electrical signal that represents a communication signal, communication signal with noise, pure noise, or any combination thereof, etc. The input signal may be a command signal, a carrier wave signal, a modulated signal, etc.

Signal input 102 it is illustrated generating a white noise semi-sinusoidal waveform basically under 20 kHz. This waveform is present on Vin input line 104. This signal proceeds through R3 resistor 108 which is 1.0K ohms. Resistor 108 is optional in cases where the output impedance of the signal source 102 is high enough that it is not needed. For example, if the output impedance of a microphone is 1.0K ohms, resistor R3 is not needed in the circuit. Similarly, capacitor 106 may not be needed in the circuit for example if the microphone has an internal isolation capacitor or generates a signal which averages 0.0 V and does not ride on a DC bias voltage. In the audio frequency range, a 1000 microfarad capacitor is sufficient for capacitor 106, if needed. Next, the signal is connected to Node 750 which also feeds into the inverting amplifier 112. The output of the inverting amplifier 112 is fed to feedback resistor 116 also known as R2 which has a value of 300 kilohms. As seen in the circuit, the signal is also fed into RC low-pass filter 170 comprising R1 Resistor 120 at 1.0 Kohm and C1 capacitor 136 at 2.0 nano-farads. The frequency filtered output 162 is an amplified version of the voltage on the voltage input line 104, and is voltage amplified by approximately 100× such as seen if simulated in LTspice circuit simulator using the simulation code listed below. The low-pass filter 170 also creates a delayed signal version of the input to amplifier 112. This delayed signal is then attenuated by 300 Kohm R4 resistor 124 and then combined or added to 300 Kohm non-delayed all-frequency feedback resistor 116 voltage output signal and the input signal output from 1.0 Kohm resistor 108. This added combination of the three voltages present at node 750 which is input to inverting amplifier 112 is further low pass filtered by C2 2.0 nano-farad capacitor 132. Node 750 or the input to inverting amplifier 112 may also be considered to be a virtual ground.

Another way to consider the circuit 100 is that the feedback loop 160 feeds back the inverted signal and comprises two resistors, wherein 300 Kohm resistor R2 serves as an all-frequency pass attenuator and 300 Kohm resistor R4 serves as a time delayed low-frequency pass attenuator. They both pass current containing the generated inverted signal of the original input signal from inverting amplifier 112. This inverted signal contains the negative signal of the original input signal and is then attenuated through the two feedback resistances, 300 Kohm resistor 116 and 300 Kohm resistor 124. This attenuated inverted signal's current and voltage from the two feedback resistances is combined with or sums with the input current from the 1.0 Kohm R3 resistor 108. The combined voltage and current through the three resistors is further Low pass filtered by a 2.0 nanofarad C2 capacitor 132. The resulting signal created on this line also known as node 750 and as the virtual ground is then sent to inverting amplifier 112 for amplification and this feedback loop of amplification, inversion, filtering, and attenuation is repeated until the voltage on output 162 matches the voltage on input line 104 multiplied by the resulting circuit gain which in this case is approximately a gain of 100×.

More specifically, circuit 100 may be simulated by LTspice Circuit simulation code and then built, tested, and implemented in a physical hardware design. The .asc file for the circuit 100 is listed below and may be used to simulate the circuit, simulate resulting circuit details and signal artifacts arising from it such as harmonic distortion features, simulate derived circuit characteristics and phenomena, generate frequency response results. The .asc file below may also be used to generate useful variations of the circuit by varying component values such as but not limited to C1, C2, R1, R2, R3, R4, and the specific inverting amplifier chosen, such as in a heuristic manner in a tentation approach. This may be done to generate circuits achieving objectives such as but not limited to alternative circuit gain factors, input impedance, output impedance, resulting SNR, power output, input sensitivity, and/or frequency response.
SHEET 1 880 680
WIRE −64 96 −80 96
WIRE 0 96 −64 96
WIRE 112 96 80 96
WIRE 160 96 112 96
WIRE 240 96 224 96
WIRE 384 96 240 96
WIRE 384 128 384 96
WIRE 112 160 112 96
WIRE 144 160 112 160
WIRE 240 160 240 96
WIRE 240 160 224 160
WIRE −80 208 −80 176
WIRE 112 240 112 160
WIRE 144 240 112 240
WIRE 176 240 144 240
WIRE 336 240 256 240
WIRE 384 240 384 208
WIRE 384 240 336 240
WIRE 448 240 384 240
WIRE 464 240 448 240
FLAG −80 208 0
FLAG 384 304 0
FLAG 144 304 0
FLAG 112 96 err
FLAG −64 96 in
FLAG 336 240 out
FLAG 464 240 output
FLAG 448 320 0
SYMBOL Digital\\inv 160 32 R0
WINDOW 3 63 30 Left 2
SYMATTR Value vhigh=5 vlow=−5 ref=1ftd=10n
SYMATTR InstName A1
SYMBOL res 368 112 R0
SYMATTR InstName R1
SYMATTR Value 1k
SYMBOL res 240 144 R90
WINDOW 0 0 56 VBottom 2
WINDOW 3 32 56 VTop 2
SYMATTR InstName R2
SYMATTR Value 300k
SYMBOL cap 368 240 R0
SYMATTR InstName C1
SYMATTR Value 2n
SYMBOL res 96 80 R90
WINDOW 0 0 56 VBottom 2
WINDOW 3 32 56 VTop 2
SYMATTR InstName R3
SYMATTR Value 1k
SYMBOL bv −80 80 R0
WINDOW 0 −79 26 Left 2
WINDOW 3 −362 51 Left 2
SYMATTR InstName B1
SYMATTR Value V=white(2*pi*time*20k)/20
SYMBOL res 272 224 R90
WINDOW 0 0 56 VBottom 2
WINDOW 3 32 56 VTop 2
SYMATTR InstName R4
SYMATTR Value 300k
SYMBOL cap 128 240 R0
SYMATTR InstName C2
SYMATTR Value 2n
SYMBOL res 432 224 R0
SYMATTR InstName R5
SYMATTR Value 1k
TEXT −432 296 Left 2 !.tran 1m

Embodiments of the amplifier circuit 100 may be configured for use as or use with a hybrid opamp, a single bit PID controller with true anticipatory action, a tunable single bit PID controller, a high resolution bang-bang controller, a wide-band delta-sigma delta ADC modulator, an enhanced Class D power amplifier with good power supply rejection ratio and/or, a wide-band and high gain amplifier compared to analog opamps that have one or the other, a wide-band voltage regulator, and integrator, a differentiator, a three stage jerk motor control (triple derivative), etc.

For instance, delta-sigma modulation is a method for encoding analog signals into digital signals. As can be appreciated, the amplifier circuit 100 may be used to generate a sigma delta bit stream of very high accuracy that is encoded with an input signal pre-emphasized for the output filter. The sigma delta stream contains a signal with negative group delay equal to positive delay of the system delay (e.g., the positive delay is the filter delay of the bitstream filter, the negative delay cancels the positive delay producing a nearly identical analog copy of the input without delay).

As can be appreciated, embodiments of the amplifier circuit 100 may be used as a PID controller (e.g., a single-bit PID controller). An improved PID controller may be formed by using the amplifier circuit 100 to adaptively compensate for time delays in the feedback loop of the PID controller. Generally, a PID control uses closed-loop control feedback to keep the actual output as close to the target or setpoint output as possible. This may be done by using the feedback to continuously calculate an error value as the difference between a desired setpoint and a measured process variable, wherein a correction based on proportional, integral, and derivative terms may be applied. Thus, a PID loop forces the output to match the input. This PID loop creates a delay—e.g., a negative pulse train used in the PID controller comprises a negative group delay created by the PID loop, forcing the output to match the input. Use of the amplifier circuit 100 as a PID controller, however, may be used to produce output signals that nearly match the input signal but with no delay.

As can be appreciated from the disclosure herein, embodiments of the amplifier circuit 100 may be created by summing three voltages and quantizing the error which is a derivative of the input signal. For instance, the input voltage, the negative bitstream voltage from the quantizer, and the negative RC filtered voltage of the bitstream may be resistively combined to create a virtual ground. The voltage at the virtual ground is the error signal of the feedback loop. The amplifier circuit 100 may be configured as a derivative control circuit with the ability to adjust the time delay of the output signal, which may involve adjusting into the negative region. In addition, the amplifier circuit 100 may produce an adjustable order of magnitude sigma-delta modulated bitstream.

Embodiments of the amplifier circuit 100 may be configured as follows:
The input signal: one connection.
The input resistance.
The output signal: three connections.
The integral feedback resistance.
The integral amplifier resistance.
The integral amplifier capacitance.
The Sigma Delta Bitstream: three connections.
The hard limiter output.
The derivative feedback resistance.
The integral feedback resistance.
The Virtual Ground: five connections.
The input resistance.
The hard limiter input.
The derivative feedback resistance.
The anti-aliasing capacitance.

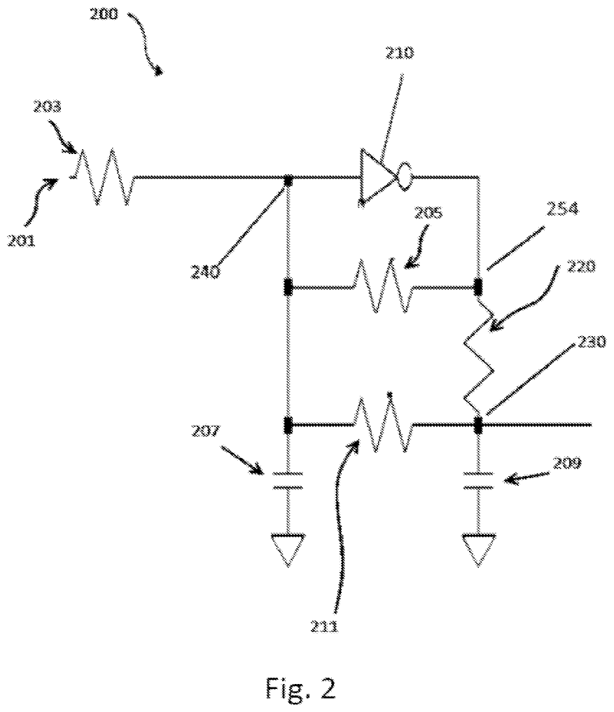

FIG. 2 illustrates a near-minimal circuit topology 200 for an embodiment of the amplifier circuit using a inverter. While the aliasing capacitor 207 could be removed in some cases and still function with a smaller convergence range, all of these components are necessary for more optimal operation. Specifically, resistor 203 limits current from signal input 201. Inverting amplifier 210 may be highly non-linear such as in a digital inverter or maybe significantly linear. All frequency pass resistor 205 is shown connecting between the input and output of inverting amplifier 210. RC filter comprised of resistor 220 and capacitor 209 is shown and it both provides lowpass functionality at the output signal connection 230 and also low pass and delayed signal to attenuating resistor 211. Capacitor 207 further filters high frequencies present in the current passing through resistor 211 and resistor 205. Circuit point 240 here is common to the outputs of resistors 203, 205, 211 and the input to inverting amplifier 210. The original signal from resistor 203 is added to the inverted all pass signal from resistor 205 and the delayed inverted lowpass signal from resistor 211 and frequency filtered by capacitor 207 to generate the combined input into inverting amplifier 210.

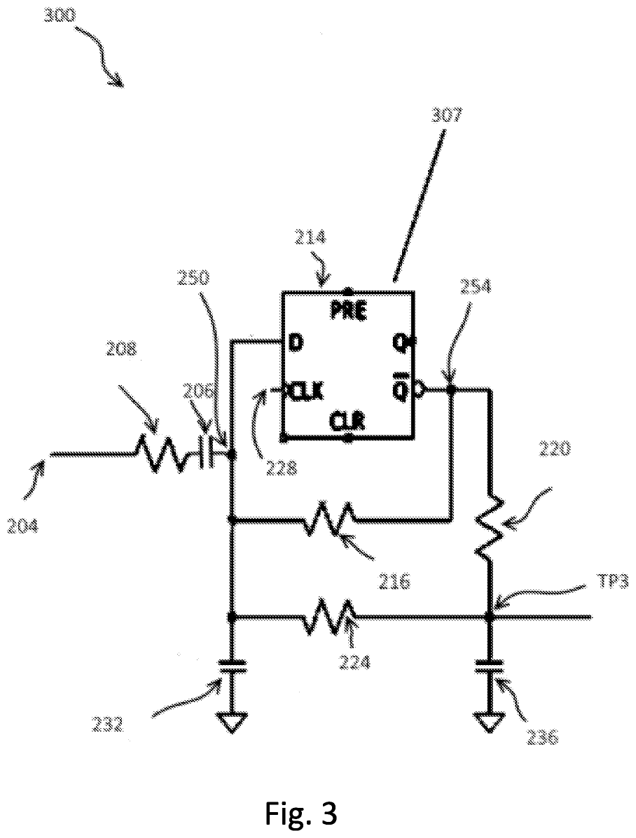

FIG. 3 illustrates a near-minimal circuit topology for an embodiment of the amplifier circuit using a clocked flip-flop topology amplifier 300. While the aliasing capacitor 232 could be removed in some cases and still function with a smaller convergence range, all of these components are recommended for more optimal operation. Specifically, resistor 208 limits current from signal input 204. Capacitor 206 is optional and maybe needed to isolate amplifier 300 from its input source, especially if its input source is providing an unwanted DC bias. Flip flop 307 is clocked through clock pin 228 from a clock oscillator not shown and which runs typically at a minimum of a frequency of 10x the bandwidth of the resulting amplifier circuit. Flip flop Output 234 connected to the inverting output of the flip flop 307 is also connected to all frequency pass resistor 216 and to RC filter resistor 220 and capacitor 236. Circuit point 237 is both the output of amplifier 300 and input to low pass frequency attenuator resistor 224. The circuit works similar to the circuits and FIG. 1 and FIG. 2 with the exception of the clocking the present on the flip-flop generating a chopped digital signal at output not Q based on the clocking frequency. The circuit topology is Not free running and relies on the clock oscillator

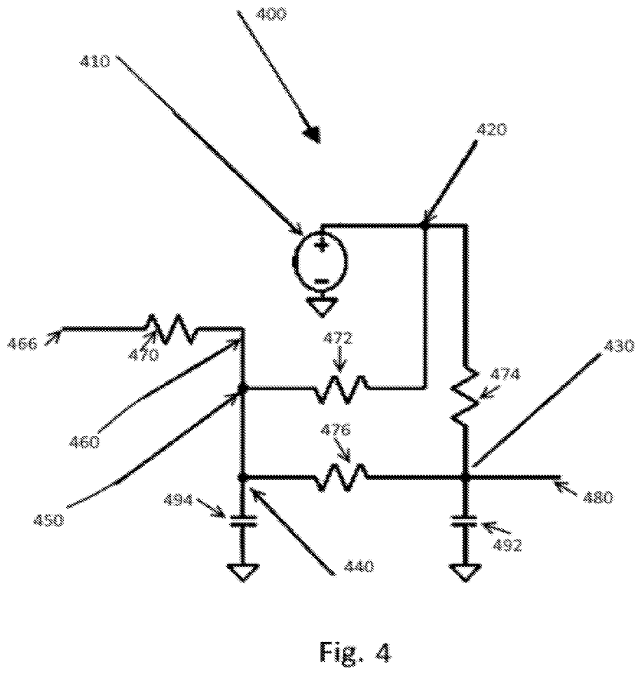

FIG. 4 illustrates an exemplary signal processing circuit topology for an embodiment of the amplifier circuit 400 showing the circuit topology mathematically. Input voltage signal is connected at 466 to a resister 470 that is connected to a ground through an aliasing capacitor 494 and a connection or a node 440. Resisters 472, 474 and 476 are connected to a positive side of the Loginverter 410. Capacitor 492 is also shown. Output voltage signal 480 is at a node or connection 430. The signal processing amplifier circuit 40 may be associated with an equation

V=If (delay(V9vGND), td)>0,−1,1)

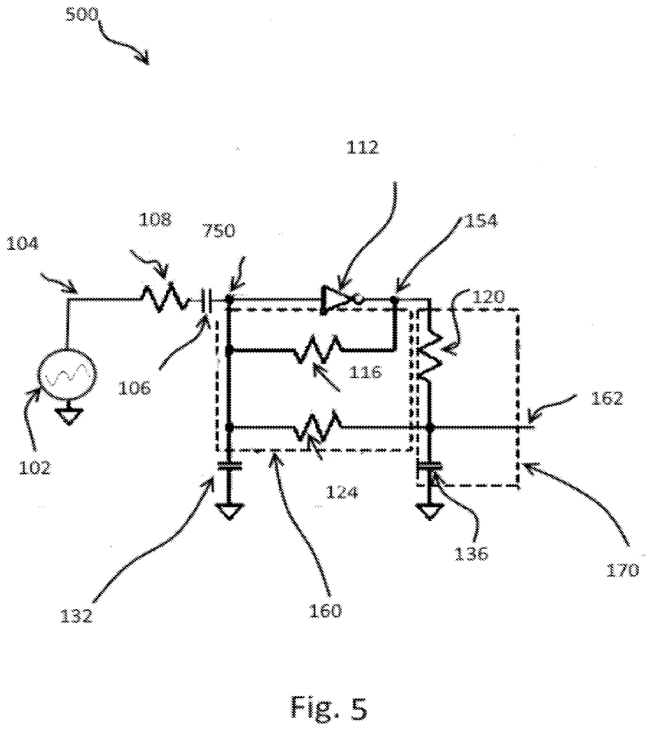

FIG. 5 illustrates an exemplary circuit topology 500 for an embodiment of the amplifier circuit shown in FIG. 1 The circuit topology is free running. More specifically, signal 102 may be an input from 100 Hertz to 1000 Hertz at a voltage input of 0 to 1 V. The output of signal 102 goes into Vin 104 it and then into 10 K input resistor 108. Blocking capacitor 106 at 100 microfarads blocks any DC component from signal 102. A logic inverter 112 may be a NAND gate CD4011BE with two of its inputs tied together to create an inverter. Resistor 120 may be 10 K ohms as is resistor 124 being 10 K ohms. Capacitor 136 may be 0.8 nanofarads as is anti-aliasing capacitor 132 0.8 nanofarads. All frequency pass resistor 116 maybe 1.0 Mega ohm. The circuit results in an inverted voltage output from the input signal.

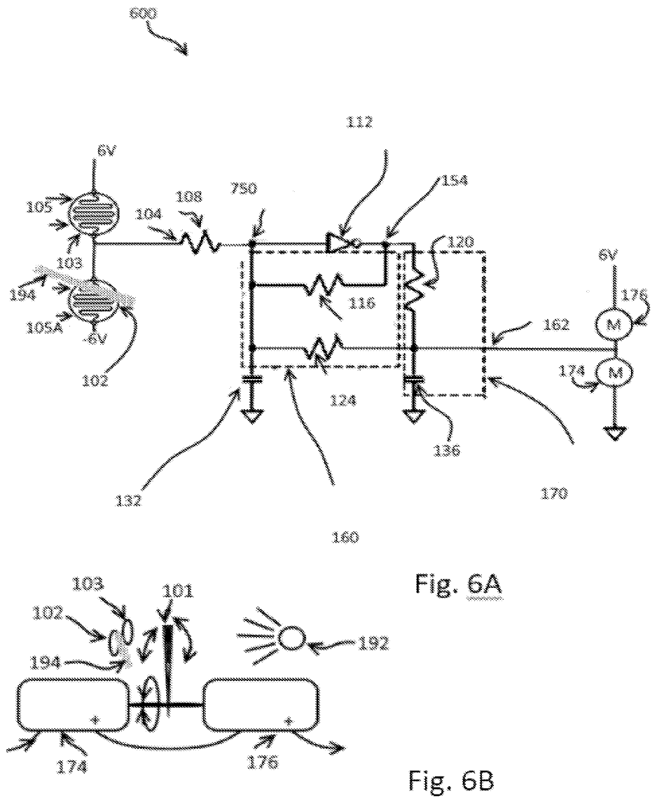

FIGS. 6A-6B illustrate an exemplary circuit topology 600 for an embodiment of the amplifier circuit shown in FIG. 1 with specific components and component values and designed to maintain an ‘inverted pendulum’ in inverted position: The circuit topology is free running. Inverted pendulum 101 is shown upright and casting a shadow between light sensors 103 and light sensor 102 from light source 192. Loads, such as motor 174 and a motor 176 are controlled by the circuit topology 600 to maintain the pendulum in the inverted position. The combined voltage output of the light sensors 104 is sent to resistor 108 and to the circuit design as seen in FIG. 1. Inverting amplifier 112, all pass resistor 116 (may be a 10K), low pass attenuating resistor 124, anti-aliasing capacitor 132, low pass resistor 120, and anti-aliasing capacitor 136 are shown as functioning the same as in FIG. 1. The individual values of these components maybe optimized to drive the specific motors 174 and 176 used to maintain the inverted pendulum 101 in position by connecting to output 162. RC low pass filter 170 and attenuators 160 also function as seen in FIG. 1.

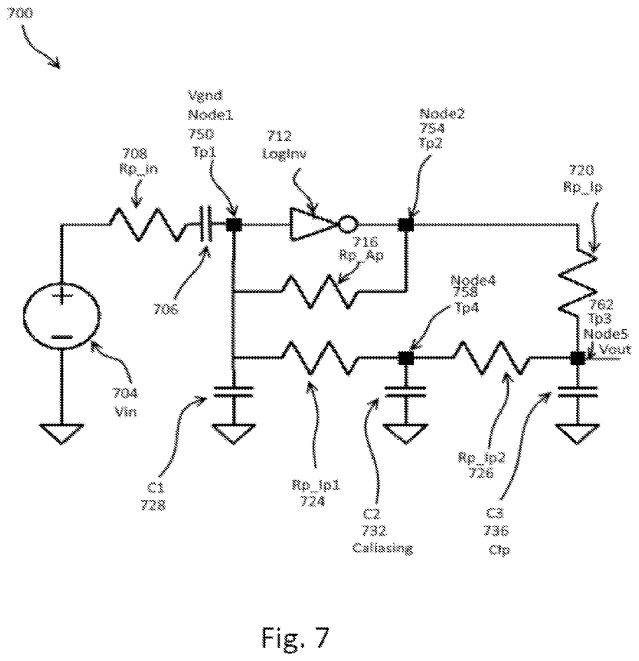

FIG. 7 illustrates an exemplary circuit topology 700 for an embodiment of the amplifier circuit which offers an enhancement over FIG. 1. The circuit topology is free running.

Referring to FIG. 7, the amplifier circuit 700 includes a resistor 708 Rp_ᵢₙ. Rp_ᵢₙ 708 is configured to receive input (e.g., an input signal) 704. The input signal 704 is an electrical signal that may represent a communication signal, a communication signal with noise, pure noise, or any combination thereof, etc. The input signal 704 may be a command signal, a carrier wave signal, a modulated signal, etc. Rp_ᵢₙ 708 is connected to Node1 750 which is or may be considered to be a virtual ground V_{GND} 750. V_{GND} 750 may be created by a resistor divider. The resister divider may include resistors Rp_ₐₚ 716, Rp_{_lp} 720, Rp_{_lp1} 724, and Rp_{_lp2} 726 connected as shown. The resister divider forms a feedback loop, wherein Rp_ₐₚ 716 serves as an all-frequency pass and Rp_{_lp} 720 Rp_{_lp1}, 724 and Rp_{_lp2} 726 serves as a low-frequency pass. For instance, Rp_ᵢₙ 708 is connected to Node1 750, Node1 750 being V_{GND} 750 as formed by the resister divider combination of Rp_ₐₚ 716 and Rp_{_lp} 720, Rp_{_lp1} 724 and Rp_{_lp2} 726. Node1 750 is also connected to a logic inverter Logᵢₙᵥ 712, Logᵢₙᵥ 712 having an input and an output. The output of Logᵢₙᵥ 712 is connected to Node2 754. For instance, one end of Rp_ₐₚ 716 is connected to Node1 750 (which is or may be considered to be a virtual ground V_{GND} 750), Node₁ 750 is connected to the input of logic inverter Logᵢₙᵥ 712, and the output of logic inverter Logᵢₙᵥ 712 is connected to Node2 754. Node1 750 is connected to one side of Rp_ₐₚ, 716, and the other side of Rp_ₐₚ, 716 is connected to Node₂ 754. Node₂ 754 is connected to one side of Rp_{_lp} 720 and the other side of Rp_{_lp} 720 is connected to Node5 762. Node5 762 is connected to capacitor Cₗₚ 736, wherein Rp_{_lp} 720 and Clₚ 736 form an RC lowpass filter. Node₄ 758 is connected to capacitor C_{aliasing} 732, wherein C_{aliasing} 732 provides signal aliasing (e.g., causes different signals to become indistinguishable (or aliases of one another) when sampled). Cₗₚ 736 is connected to ground. C_{aliasing} 732 is connected to ground. Nodes 762 is configured to provide the output of the circuit (e.g., an output signal). C1 728 provides additional lowpass filtering for input to Logᵢₙᵥ 712. The blocking capacitor 706 is optional depending on the nature of the input signal 704, which may be an AC signal or an AC signal riding on a DC bias.

In operation, a voltage at Vᵢₙ 704 causes a current to flow through Rp_ᵢₙ 708 to the V_{GND} 750. The feedback loop matches the input current in the two feedback resistances Rp_{_ap} 716 and Rp_{_lp} 720, Rp_{_lp1} 724 and Rp_{_lp2} 726. The ratio of the Rp_ₐₚ 716 and (Rp_{_lp} 720, Rp_{_lp1} 724 and Rp_{_lp2} 726) to (Rp_{_lp} 720 Rp_{_lp1} 724 and Rp_{_lp2} 726) (e.g., [Rp_ₐₚ 716+(Rp_{_lp} 720 Rp_{_lp1} 724 and Rp_{_lp2} 726)]/(Rp_{_lp} 720 Rp_{_lp1} 724 and Rp_{_lp2} 726) ) produces voltage gain at Vₒᵤₜ 754. The Rp_ₐₚ 716 over (Rp_{_lp} 720+Rp_{_lp1} 724 +Rp_{_lp2} 726) ratio sets the gain of the differential of the input signal. The Rp_{_lp} 720 over Rp_in 708 ratio (e.g., Rp_lp/Rp_in) substantially sets the gain of the input signal. V_{GND} 750 is the difference of the input signal 704 and a delayed input signal at 750 which is the derivative of the input signal 704. This derivative of the input signal is amplified, inverted, and applied to Rp_ₐₚ 716 and (Rp_{_lp} 720+Rp_{_lp1} 724 +Rp_{_lp2} 726). The current through Rp_ₐₚ 716 flows back into V_{GND} 750 and the current from Rp_{_lp} 720 flows through Clp 736 and Rp_{_lp2} 726. The RC lowpass filter output voltage causes current to flow through Rp_ₐₚ 716 to V_{GND} 750.

C_{aliasing} 732 filters high frequency currents from the V_{GND} 750 above the lowpass filter frequency bandwidth. RC lowpass filter comprising Rp_Ip 720 and Clp 736 and Rp_Ip2 726 and Caliasing 732 and Rp_Ip1 724 and C1 728 filters the amplified inverted differential voltage to produce a filtered signal without the delay that would normally be experienced when filtering a signal. The amplified inverted signal contains a derivative of the input signal which compensates for the delay of the RC lowpass filter, returning the amplified negative group delayed signal back to the original signal's time with large gains and flat frequency response.

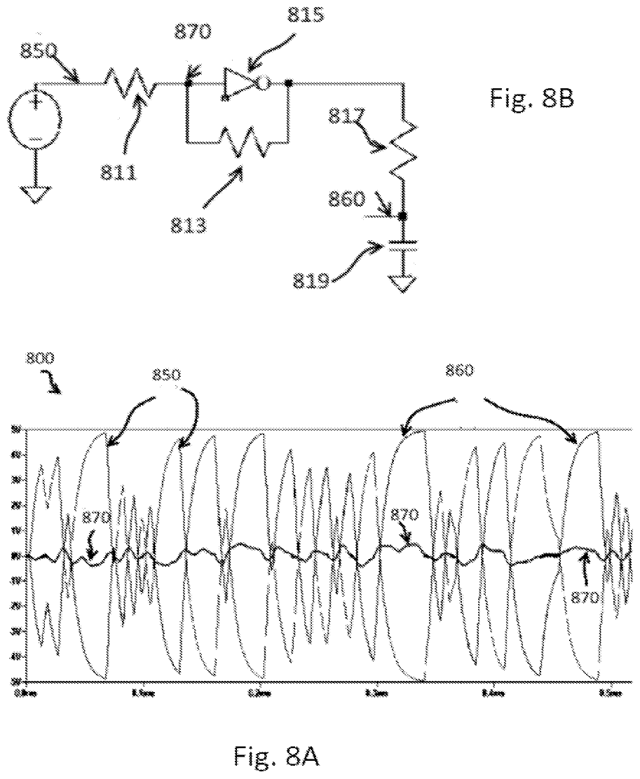

FIG. 8A illustrates a graph of the input voltage 850 and the output voltage 860 of the circuit and also the voltage at node 870.

FIG. 8B illustrates an exemplary signal processing circuit topology 800 that may generate the graph of FIG. 8A. The signal processing circuit 800 is free running. Signal input line with input voltage 850 feeds resistor 811, that may be a 10K ohms, into an inverting amplifier 815 at circuit point 870. All frequency feedback resistor 813, that may be a 1000 K ohms) connects the output of inverting amplifier 815 to its input. RC filter created by resistor 817 and capacitor 819 eliminate high frequency noise present at output voltage 860.

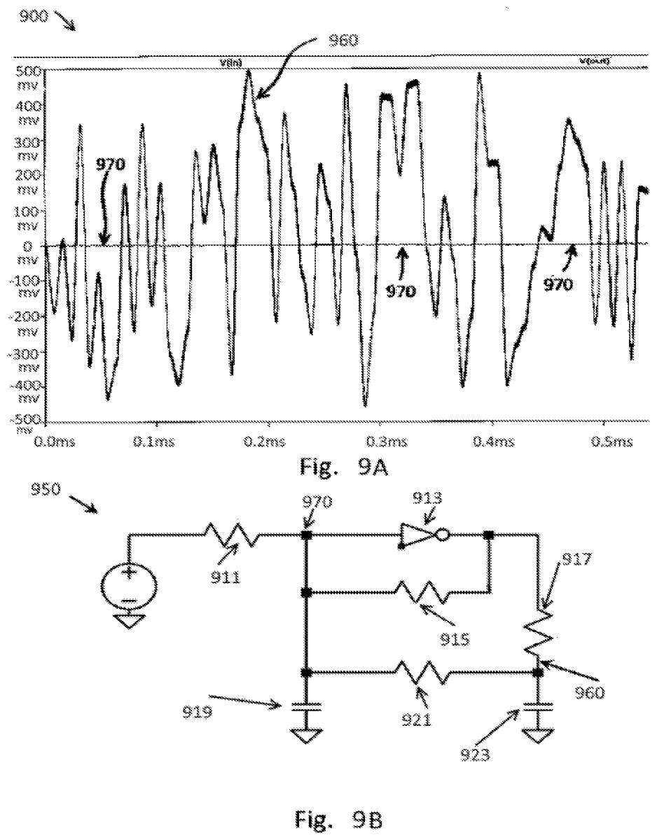

FIG. 9A illustrates an exemplary circuit topology for an embodiment of the amplifier circuit shown in FIG. 1 to be contrasted with the embodiment in FIG. 8 And with two additional components, resistor 921 and capacitor 919. The circuit topology is free running. FIG. 9 particularly points out the reduced noise in voltage plot of Verr 970 of Vout 960. Inverting amplifier 913 is shown as is all frequency past resistor 915 RC filter capacitor 923 and RC filter resistor 917. Again, the circuit may also be simulated using LTspice circuit simulation software and component values the same as or similar to those described in FIG. 1.

FIG. 9B it is the voltage plot of FIG. 9A.

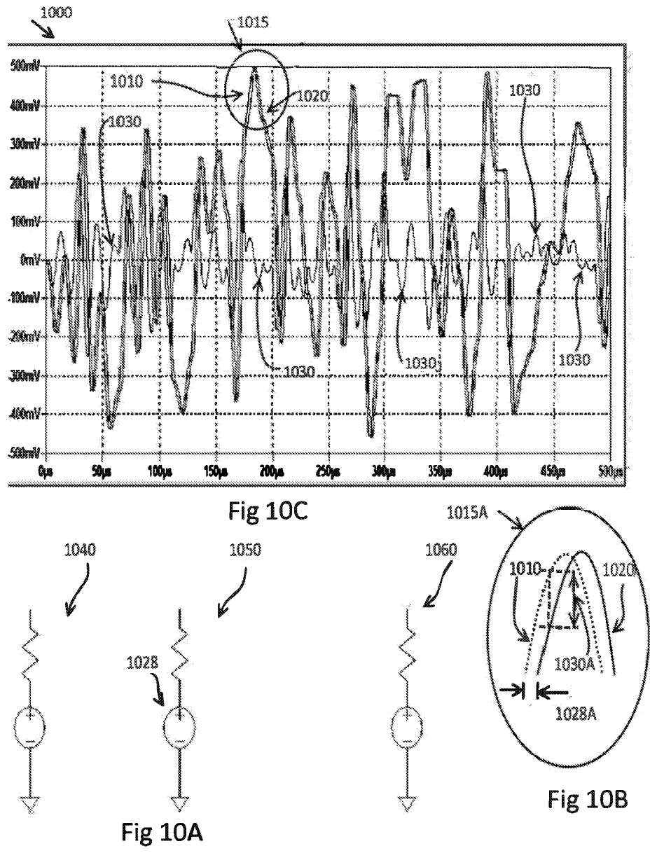

FIG. 10A illustrates how a derivative of a signal may be created by subtracting a delayed signal from its original source signal. A graph 1000 illustrates a source signal 1010 input, a delayed signal 1020 of the source generated from the source signal, and a derivative signal 1030 created by subtracting the delayed signal 1020 from the source signal 1010. The delayed signal 1020 in the figure is illustrated and delayed by 2000 ns as shown in circuit 1050 and the specific value 2000 ns is pointed to by delay value 1028. Graph region 1015A details the effect of the delay time of 2000 ns as pointed to by 1028A which is the delay between the source signal 1010 and delay signal 1020. The instantaneous derivative value 1030A is seen in 1015A as the Y-axis graph distance at a point in time corresponding to the voltage difference between the source signal 1010 and delayed signal 1020 at that point in time. Graph region 1015A is a magnified section of the original signal 1010 and delayed signal 1020 to illustrate them more clearly and pointed out in graph region 1015. Circuits 1040, 1050, and 1060 shown and modeled in LTspice software generate the source signal 1010, source delayed signal 1020, and derivative signal 1030 shown in graph 1000.

FIG. 10B illustrates a randomized waveform created by FIG. 10A.

FIG. 10C and specifically region 1015A illustrates a magnification of region 1015.

Referring to FIGS. 10A-10C, illustrated is a fact that a derivative signal may be created by subtracting a source signal from a delay of the source signal. The amount of the delay to be created may be chosen based on the speed of the active components used such as the FETs, inverters, bipolar transistors, IGBTs, BJTs, MOSFETs, electron tubes, etc. The amount of the delay to be created may also be controlled based on passive components such as resistors, capacitors, and inductors forming time constants or filter group delays in feedback circuits. Other delays and delay amounts may be formed by lengths of wires or circuit traces. FIG. 10 circuit and graphs may be copied, generated, and understood by anyone of ordinary skill in the art by using LTspice circuit simulation software.

Varactor diode based capacitors may be applied and used with additional biasing component circuitry (not shown) to adjust overall capacitances and the amount of delay in the circuit and the voltage difference span used to create the derivative. A lower capacitance may be set within a varactor diode by adjusting its bias voltage upward and increasing the distance of the depletion region within the varactor diode. This lower capacitance may be purposely adjusted downward to be used in a higher speed circuit with faster responses offered. Alternatively, a higher capacitance may be set within a varactor diode by adjusting its bias voltage downward. This higher capacitance may be purposely adjusted upward to be used in a lower speed circuit and may also reduce noise sensitivity in a lower speed circuit. Thus the circuit may be dynamically modified to adjust to its response requirements.

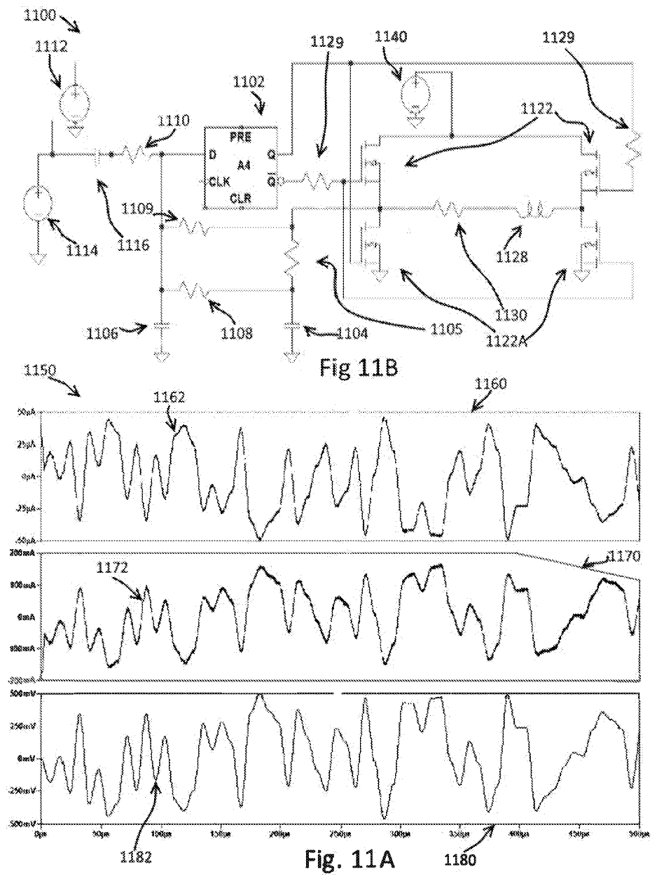

FIG. 11B illustrates a specific version of FIG. 3 circuit with specific component values simulated and implementing MOSFETs with results derived. More specifically, a signal source 1114 generates a signal fed into capacitor 1116 which is 100 microfarads. The output of the capacitor 1116 is then fed into resistor 1110 or R25 with 10 kilohms resistance. Flip-flop 1102 receives the output from R25, resistor 1110 into its ‘D’ Digital Data line input. The Q output is shown to feed two transistors such as BSS145 mosfets. Similarly, the not Q line or inverted Q line is shown to feed to other transistors such as BSS 145 mosfets. Resistor 1129 may be of minimal resistance such as 1Ω. The output of the transistor pairs is shown feeding resistor 1130 which may be 10Ω through inductor 1128 which may be 100 micro Henries. Resistor 1105 which is 10 K is shown connected to an output pair of the transistors and all so connected to a 1.4 nanofarads capacitor 1104, a 10 K resistor 1108, and a 100 Mega ohm resistor 1109. A capacitor 1106 at one Pico farad is shown connected to resistor 1108 and resistor 1109 and resistor 1110 and flip-flop 1102 on its D input. The flip-flop 1102 is clocked at an appropriate rate such as 10 MHz.

FIG. 11A illustrates the resulting simulated waveforms generated by the circuit of FIG. 11B. Graph 1180 illustrates output voltage 1182 across inductor 1128. Graph 1160 illustrates the input current 1162 through Input resistor 1110. Graph 1170 illustrates resulting amplification of the circuit and the current through resistor 1130 and through coil 1128 it which may be a speaker coil.

Graph 1160 illustrates input current to be between −50 microamps and 50 microamps. Graph 1170 illustrates output current do be between −200 mA and positive 200 millamps. Thus significant gain is shown with little or no distortion.

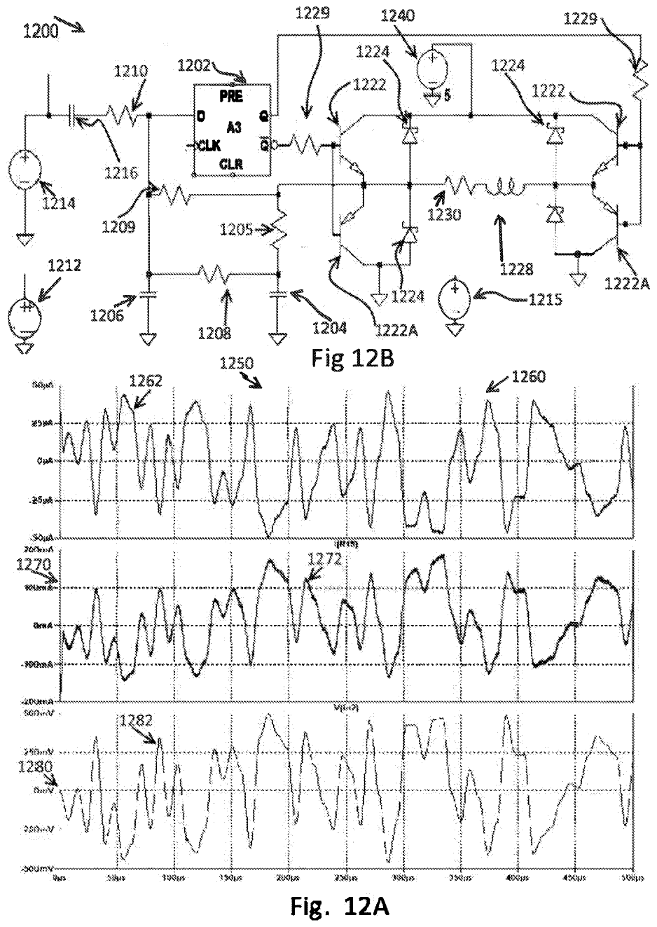

FIG. 12A graphs show corresponding current of a circuit in FIG. 12B. All corresponding graphs have the same X and Y axes limits and units.

FIG. 12B illustrates another specific version of FIG. 3 circuit with specific component values simulated and implementing Bipolar Transistors Instead of mosfets with similar results derived.

Differences between FIG. 11B component values and FIG. 12B component values are as follows. Resistor 1229 is 250Ω. The transistor 1222 is a 2N3904. Transistor 1222 A is a 2N3906. Diode 1224 is a BAT54 zener diode. All other components are the same values corresponding to FIG. 11B.

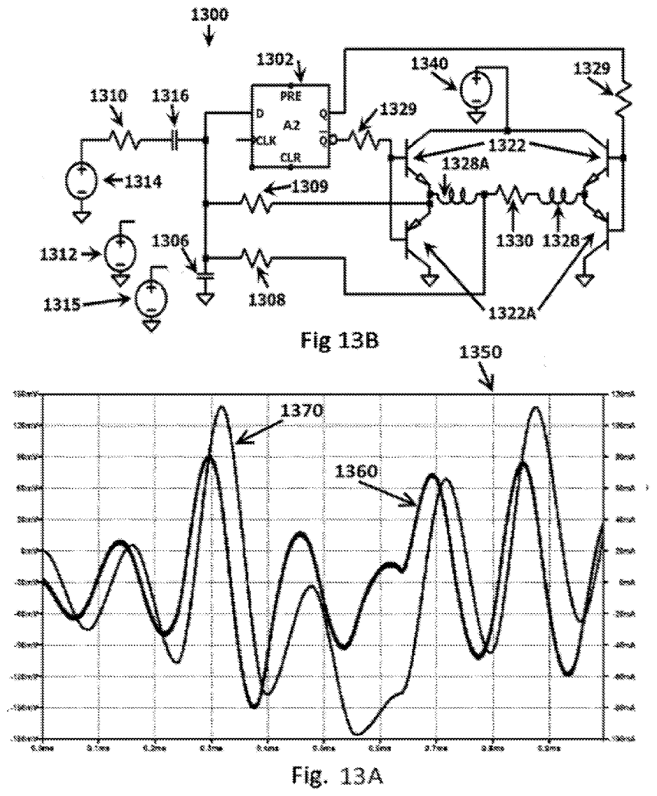

FIG. 13B illustrates another specific version of FIG. 3 circuit with specific component values simulated and implementing Bipolar Transistors with results derived. It specifically graphically illustrates the simulated input voltage and output current vs. time for a randomized input signal.

FIG. 13B illustrates coil 1328 which may be a speaker coil and 50 micro Henries. It illustrates resistor 1330 at 10Ω. It illustrates transistors 1322 as 2N3904 and transistors 1322A as 2N3906. And FIG. 13A illustrates the input voltage 1370 and output current 1360 through coil 1328.

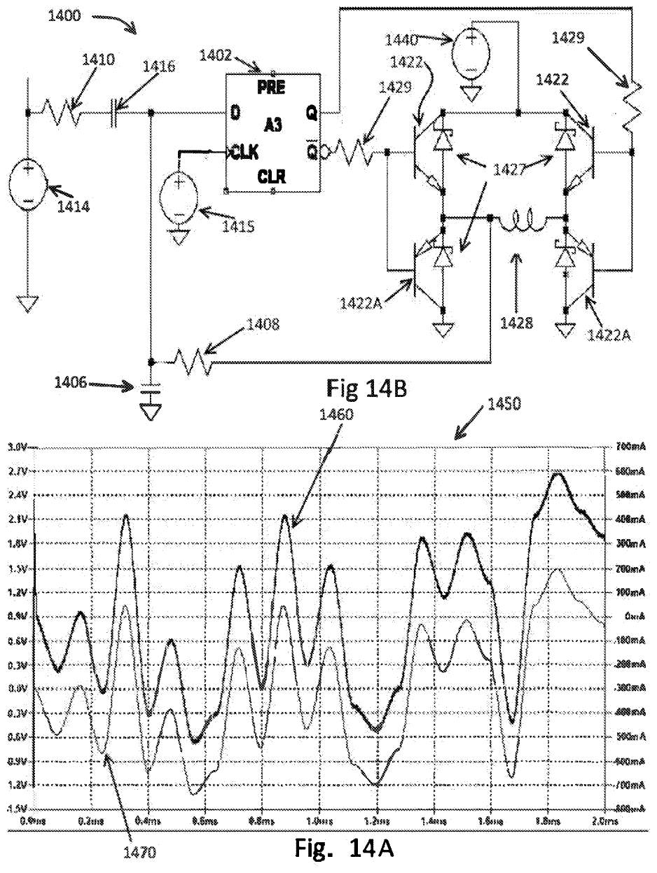

FIG. 14B illustrates another specific version of FIG. 3 circuit with specific component values simulated and implementing Bipolar Transistors with results derived. It specifically graphically illustrates the simulated input voltage and output current vs. time for a randomized input signal.

FIG. 13A illustrates the simulated input voltage 1470 and output current 1460 results.

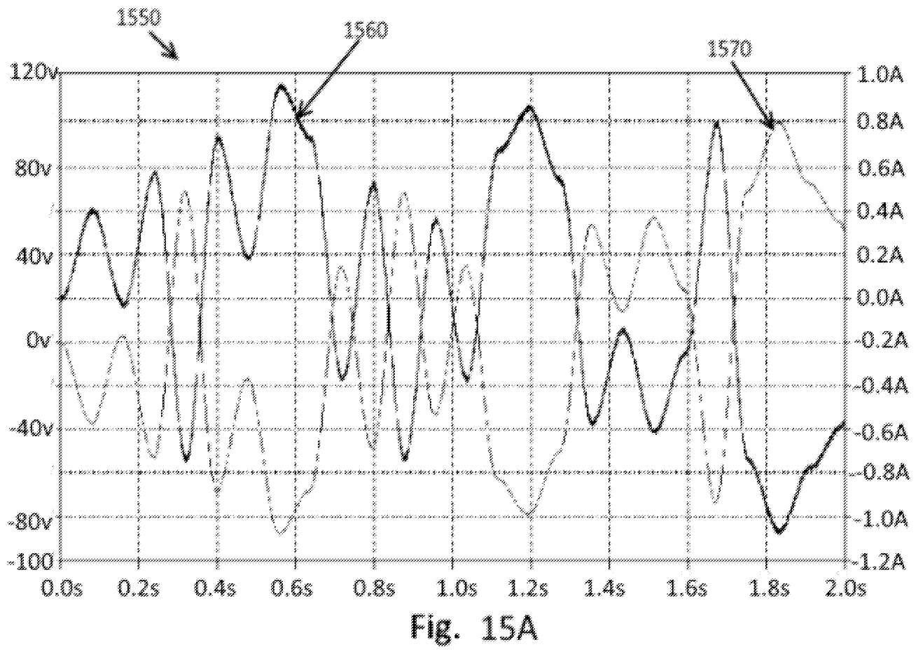

FIG. 15B illustrates another specific version of FIG. 3 circuit with specific component values simulated and implementing Bipolar Transistors with results derived. It specifically graphically illustrates the simulated input voltage and output current vs. time for a randomized input signal for an output circuit differing from the other examples.

FIG. 15A illustrates Input voltage curve 1570 and output current curve 1560 (1.0 Amp to −1.2 Amp span) resulting from circuit 15B. Specifically, the transistor 1522A is a 2N3906 and transistor 1522 is a 2N3904.

Resistor 1529 is 250Ω. Resistor 1509 is 5 K ohms. Resistor 1508 is 1Ω. Capacitor 1506 is 2200 microfarads. Resistor 1510 is 1 K ohms. Resistor 1511 is 50Ω. Capacitor 1507 is 100 microfarads. Resistor 1584 is 0.1Ω. And coil 1528 is 1.0 Henry.

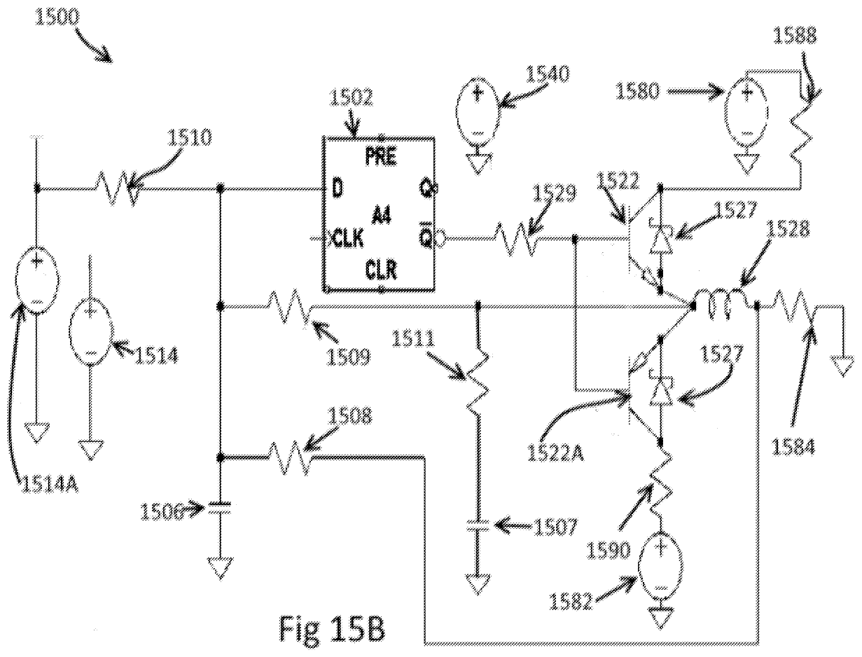

FIG. 16 illustrates a signal processing circuit with proportional, integral, and Derivative elements which may arise from the circuit shown. A resister 1606 is in electrical connection with an input 1602 that may be a terminal. An element 1604 is in electrical connection with the resister 1606 through a connection or a node 1608. Resisters 1612, 1614 and 1616 are also illustrated as are capacitors 1622 and 1618. The output signal can be from a node 1620.

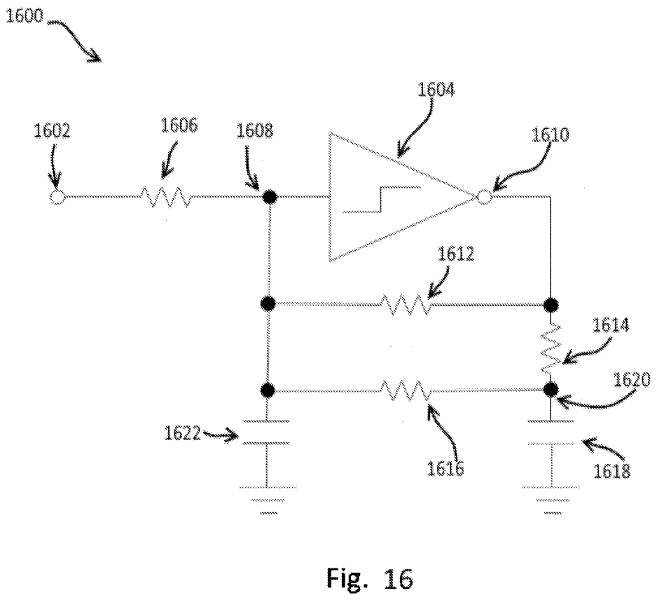

FIG. 17B illustrates an exemplary free running circuit topology for an embodiment of the amplifier circuit shown in FIG. 1 with specific components and component values and designed to create a specific voltage gain and current gain.

Specifically, resistor 1710 is 1 K ohms, resistor 1720 is 10 K ohms, RC filterCap at the output is 2.0 nanofarads and filter cap at the inverter input is 0.2 nanofarads. All frequency Hbypass resistor is seen as 15 Mega ohms. The remaining delay attenuating resistor is also 10 K ohms.

FIG. 17A illustrates a graph of the results wherein voltage in 1770 is approximately 10 times less than voltage out 1760 thus showing a 10× gain.

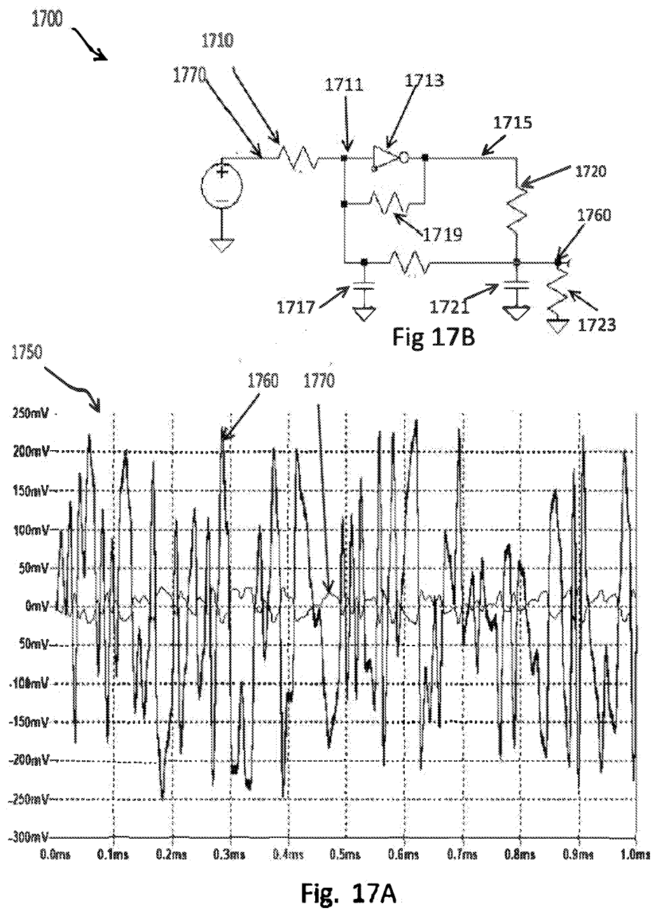

FIG. 18B illustrates an exemplary circuit topology for an embodiment of the amplifier circuit shown in FIG. 1 with specific components and component values and designed to create a different specific voltage gain and different current gain: The circuit topology is free running as opposed to a clocked circuit such as seen in FIG. 3. It creates a voltage gain of 0.1× or a reduction however it creates a substantial current gain as its output resistance as far lower.

More specifically, resistor 1810 is 100 K ohms. Resistor 1820 is 10 K ohms. All other component values are the same as FIG. 17B.

Graph in FIG. 18A illustrates input voltage 1860 to be 10× output voltage 1870.

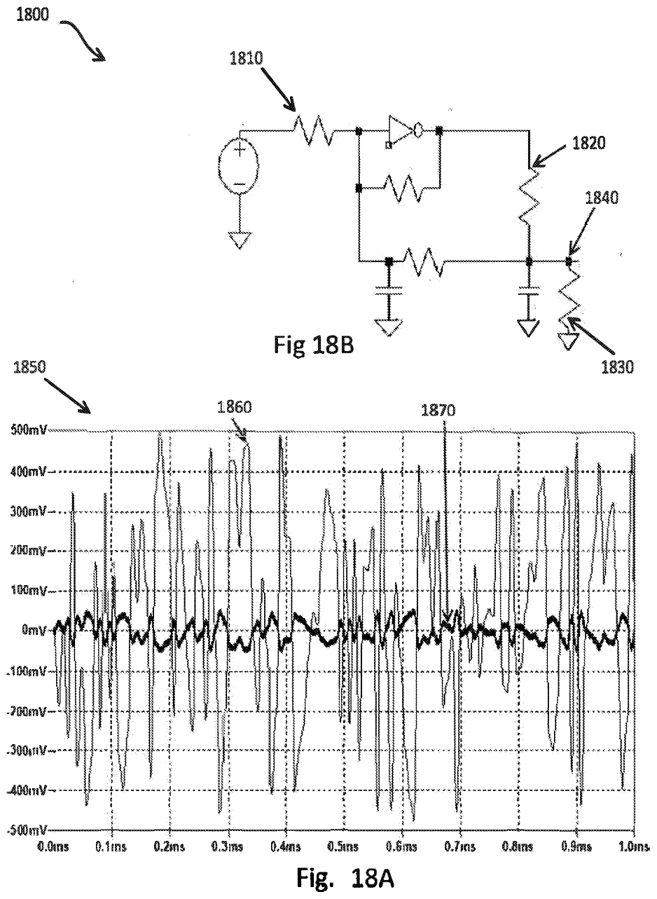

FIG. 19B illustrates an exemplary free running circuit topology for an embodiment of the amplifier circuit shown in FIG. 1 with specific components and component values and designed to create a 1× specific voltage gain and different current gain.

FIG. 19A illustrates the input and output voltages being identical in the 1x gain amplifier design.

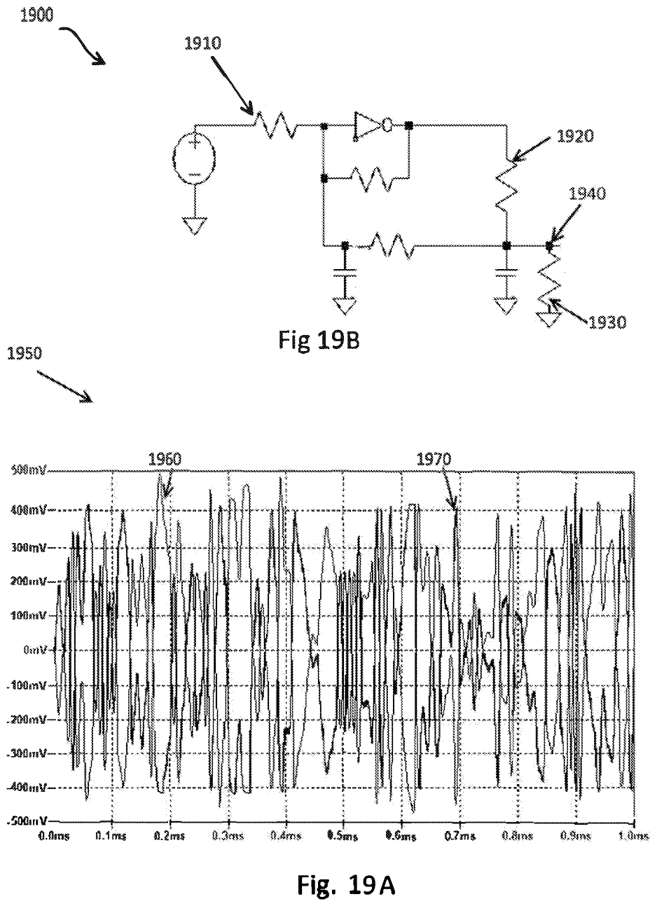

FIG. 20B illustrates an exemplary circuit topology for an embodiment of the amplifier circuit shown in FIG. 1 with specific components and component values and designed to create a different specific voltage gain and different current gain: The circuit topology is free running as opposed to a clocked circuit such as seen in FIG. 3. A voltage gain of 2.25× is created.

Resistor 2042 is 100 kilohms, resistor 2010 is 2 kilohms, capacitor 2046 is 10 nanofarads, capacitor 2048 is two nanofarads, resistor 2044 is 10 k ohms, and resistor 2020 is 10 kilohms.

FIG. 20A illustrates the resulting output voltage curve 2070 from input voltage curve 2060.

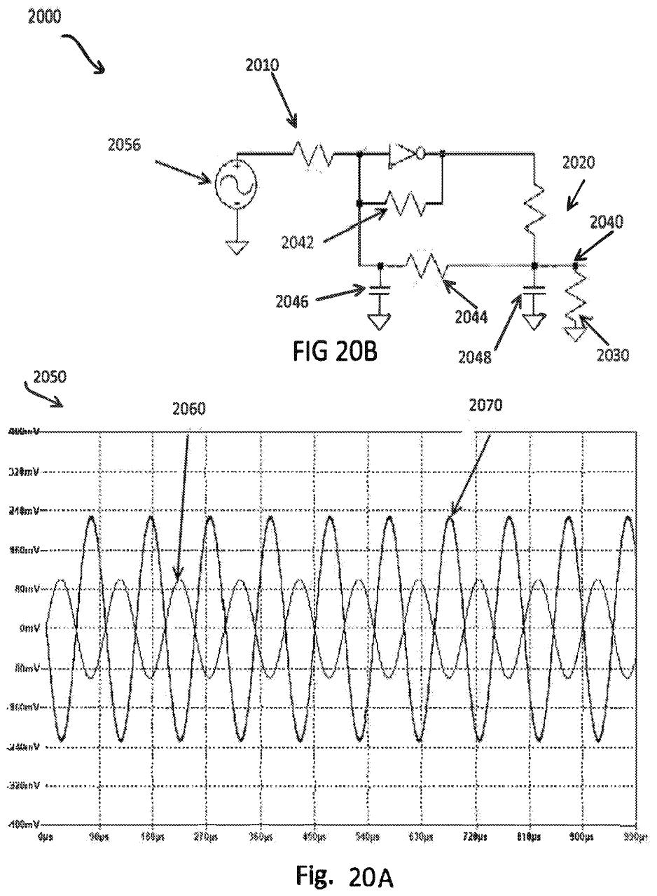

FIG. 21 is a graph showing the output of an embodiment of the amplifier circuit approaching matching of the input as the high frequency loop gain is increased.

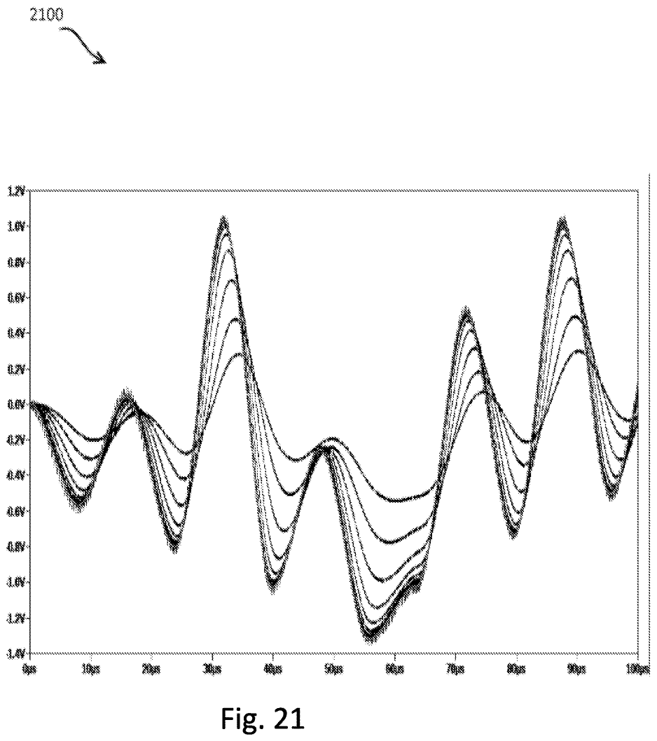

FIG. 22 is a graph showing the increasing frequency response of bandwidth of the signals in FIG. 21.

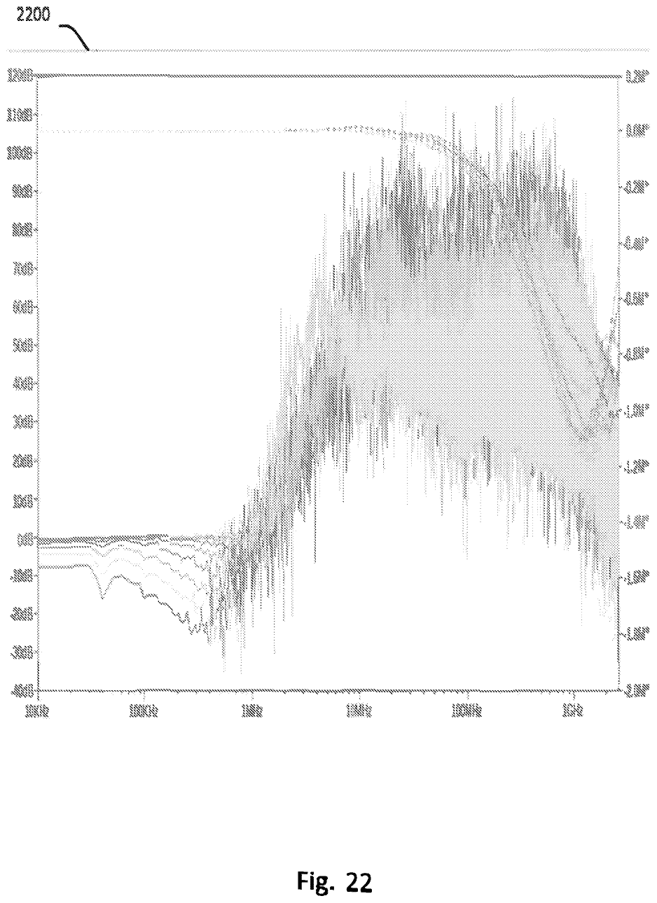

FIG. 23 illustrates a point where the high frequency gain is too large and the noise starts to increase. This is at the point of approaching zero time delay. The signal driving the amplifier has negative group delay to accomplish this. The largest triangle wave illustrates the undesirable noise when the high frequency gain is too large whereas the smaller triangle waves illustrate a less problematic noise profile.

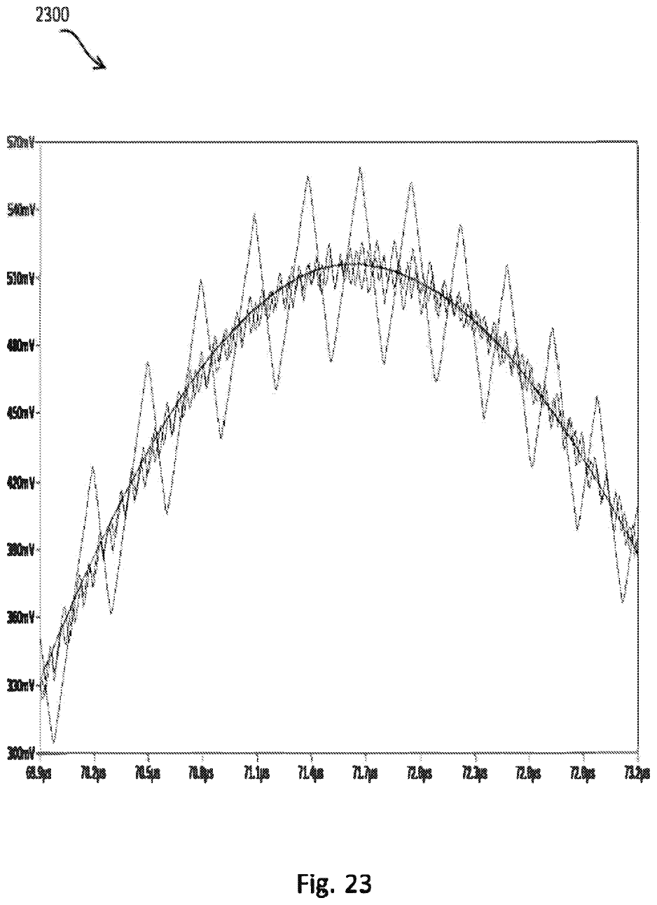

FIG. 24 illustrates an overview of the many of the circuits detailed herein.

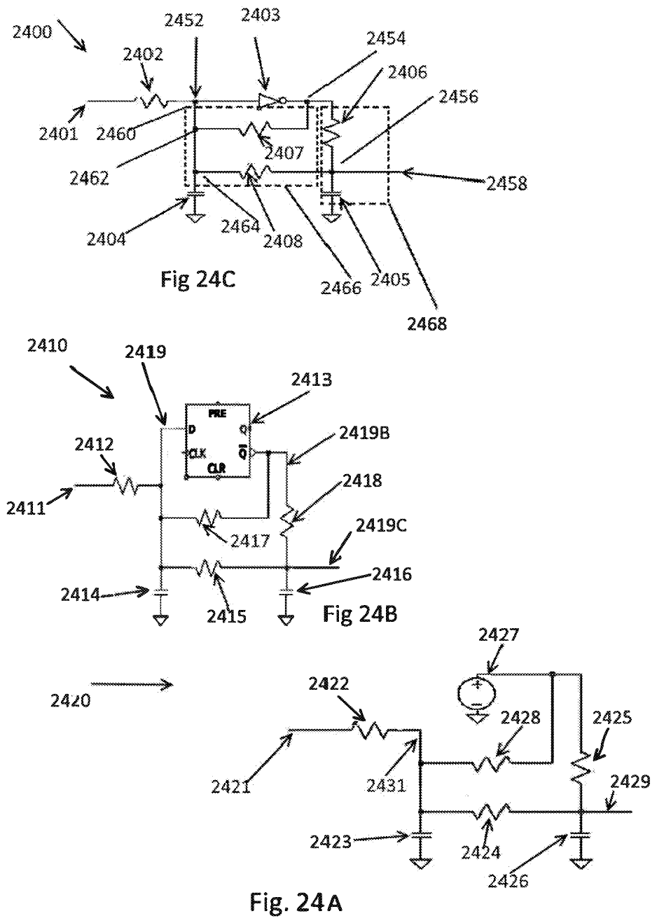

FIG. 25 illustrates FIG. 1 but detailing and naming the specific interconnect nodes.

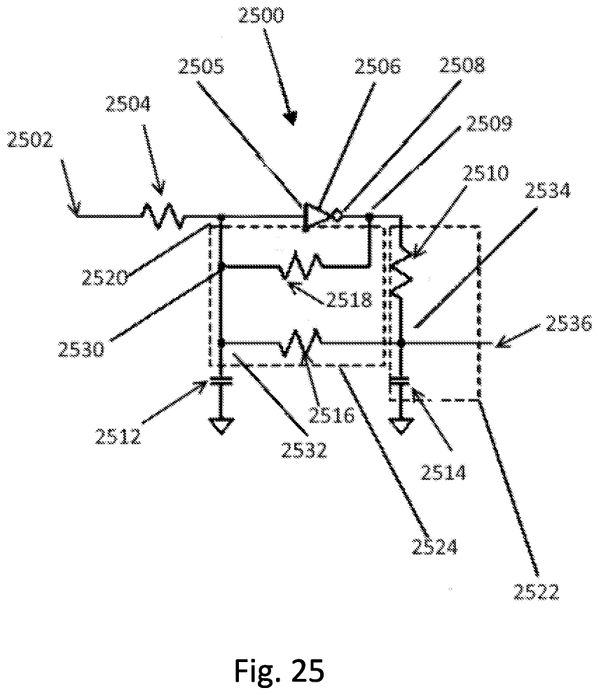

FIG. 26 illustrates the derivative created V(stage_1) 2620 to drive the second amplifier and create an output V(stage_2) 2610 that matches the input−V(in) without delay for the circuit in FIG. 7.

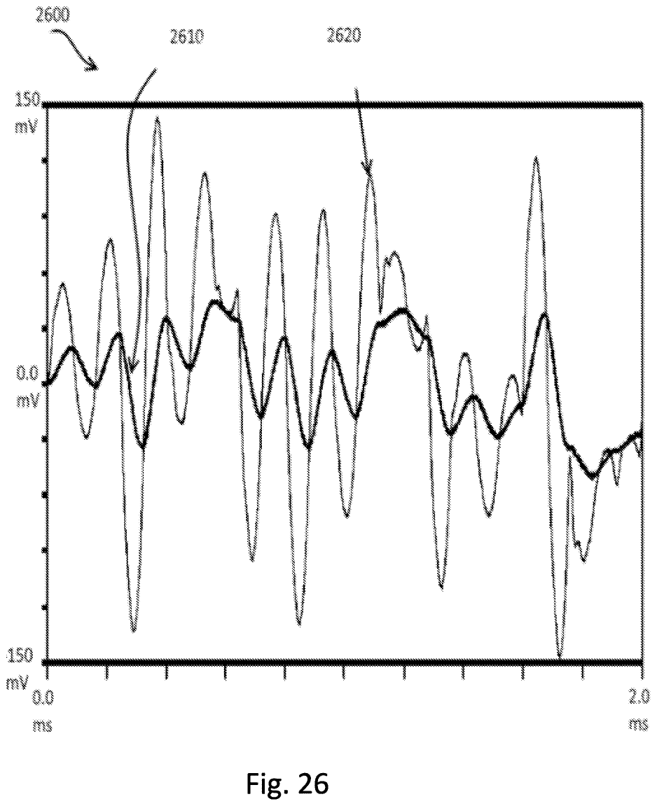

FIG. 27B illustrates a component circuit using principles embodied in the circuit of FIG. 1 wherein FIG. 27B uses an inverter created by 6 MOSFETS rather than a commercial inverter. The 6 MOSFETS may offer advantages such as much higher power output than most commercially available logic inverters. The circuit shown may have an input impedance of 500 ohms with an output impedance of 250 ohms, thus this circuit may offer a current gain. Other variations of capabilities and component values are feasible depending on user needs and may be designed using a simulator such as LTspice. This design method may be used to create or verify any of the circuit designs illustrated herein and is recommended as a useful tool. All resistors shown our 500Ω except the load resistor 2718 which is 250Ω. For example, resistors 2720 is 500Ω. Resistor 2730 is 500Ω. Capacitor 2746 is 8 nanofarads. Isolation capacitor 2752 is 1000 microfarads. Transistor 2740 is a BSS84. Transistor 2742 is a BSS123. Hi side transistor Examples are BSS84 and all low side transistors are BSS123.

FIG. 27A of circuit 27B illustrates voltage 2710 input is roughly equivalent to voltage 2712 output. However, the current output and output impedance of the amplifier may allow for a 2× current gain.

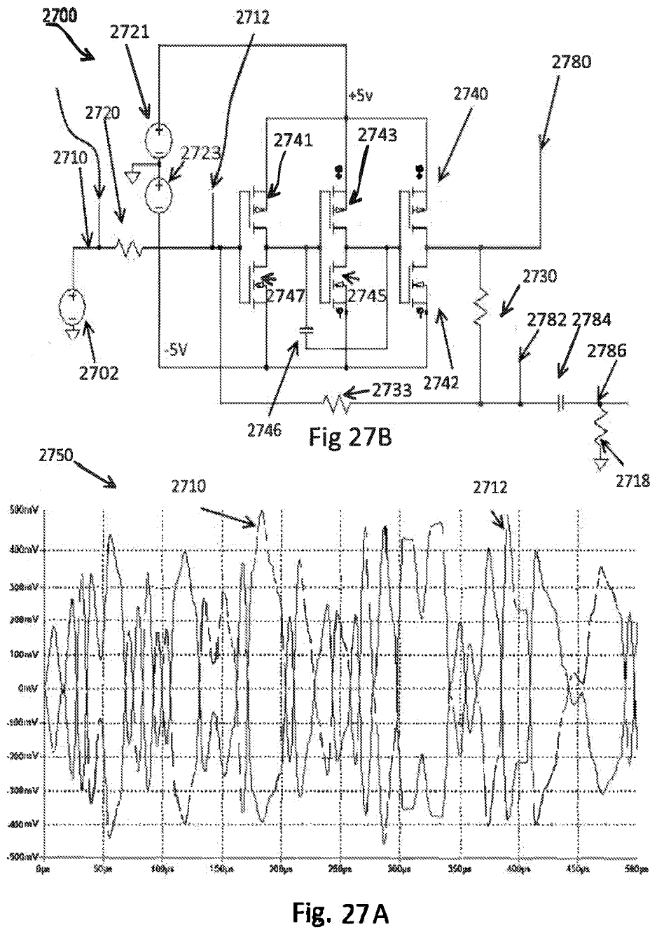

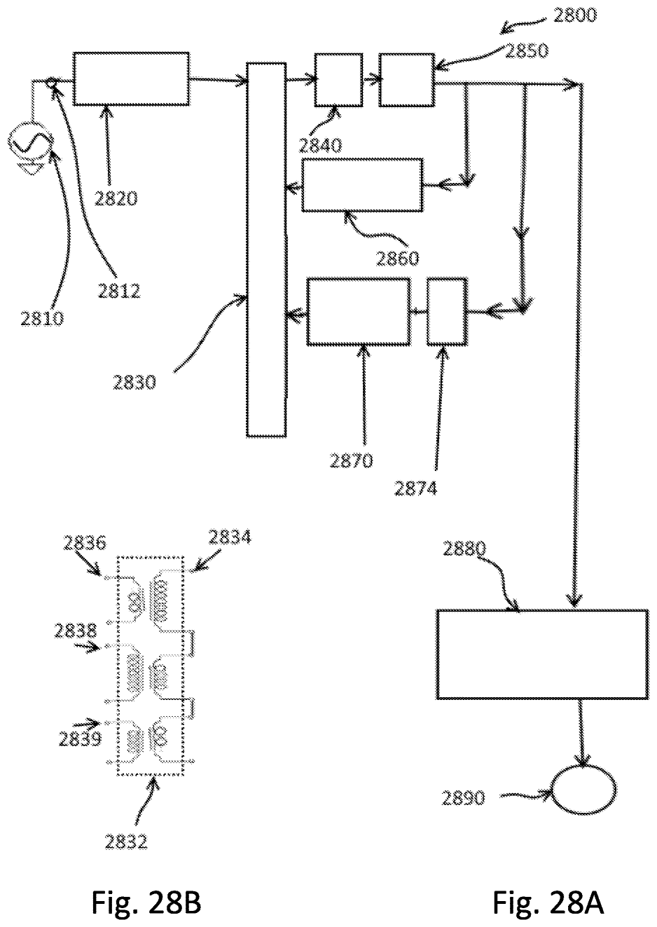

FIG. 28 illustrates a block diagram 2800 of the subject matter. Input signal 2810 arriving at an input terminal 2812 may then go into an optional attenuation circuit 2820. An input terminal 2812 may be any one of a connector such as a BNC connector, RCA jack, SMA connector, a simple plug, a terminal block. It may be optional as input signal 2812 may be connected directly or coupled directly such as by magnetic or capacitive coupling. An optional attenuator 2820 may reduce and or isolate input signal 2810 from the amplification circuit. The optional attenuator 2820 may be any one of a resistor, a transformer, an audio transformer, an RF transformer, an auto-transformer, an autotransformer with multiple taps, a toroidal ferrite core transformer with one or more input and or output windings, an inductor, a capacitor, and/or a physical attenuation means. An example of a physical attenuation means maybe the gap distance between a light emitter and light detector in an opto isolator. An optional attenuator 2820 may be an opto isolator. The output signal from optional attenuator 2820 is then fed into in addition function 2830 which combines or adds the signals from 2820, attenuator 2860, and attenuator 2870. The addition function 2830 may be a simple wire or common connection point between the signals 2820, 2860, and 2870. The addition function 2830 maybe comprised of other means such as here Transformer means or inductively coupled means adding voltages and or currents together comprised as a single component with multiple inputs or more individual components connected together. Addition function 2832 is an example wherein inputs 2836, 2838, and 2839 are added together at various specifically chosen ratios for circuit operability into a combined single signal output 2834. A further benefit of addition function 2832 is it may reverse polarities so that amplifier 2850 may be a non-inverting amplifier or an inverting amplifier. It may also serve as an isolation function in place of a blocking capacitor for input 2810 if needed. Thus, the addition function 2832 may serve not only to replace the attenuator 2860 and/or the attenuator 2870 and/or the attenuator 2820 but also add or subtract input voltages present depending on connection polarities of inputs 2836, 2838, and 2839 and/or the output 2834. The addition function 2832, embodied as a transformer, may replace the attenuator 2820, the attenuator 2870, and/or the attenuator 2860. It is further envisioned that the addition function 2832 maybe manufactured to be very small and inexpensive. The addition function 2832 may also be adapted as a plurality of opto isolators or of a hybrid opto isolator containing three light emitting sources and a single photocell, solar cell, or photo transistor. Again, in this composition polarities may be reversed and attenuation means achieved such as by the distancing light emitting sources separately and distinctly from one or more light receiving elements and or optically attenuating emitted light through a darkened light filter. Again, in this composition, it may replace attenuator 2820, attenuator 2870, and or attenuator 2860 and/or perform needed addition and or subtraction functions thus allowing for an inverting or non-inverting amplifier 2850. A low-pass filter 2840 capacitor to ground, an inductor in series, or a low pass LC circuit. A delay mechanism 2874 may be designed with an RC circuit or other delay means such as using a surface acoustic wave or simply a long wire. A low pass filter 2880 filters the high frequency components out of the output from amplifier 2850 to generate a resulting signal into output terminal 2890 for further use. A general design 2800 employs the concepts and methods used in FIG. 1, but may employ differing specific components to achieve the same result as described above. An output terminal 2890 may further comprise an optional blocking capacitor if needed.

It is the intent to cover all such modifications and alternative embodiments as may come within the true scope of this invention, which is to be given the full breadth thereof. Additionally, the disclosure of a range of values is a disclosure of every numerical value within that range, including the end points. Thus, while certain exemplary embodiments of the device and methods of making and using the same have been discussed and illustrated herein, it is to be distinctly understood that the invention is not limited thereto but may be otherwise variously embodied and practiced within the scope of the following claims.

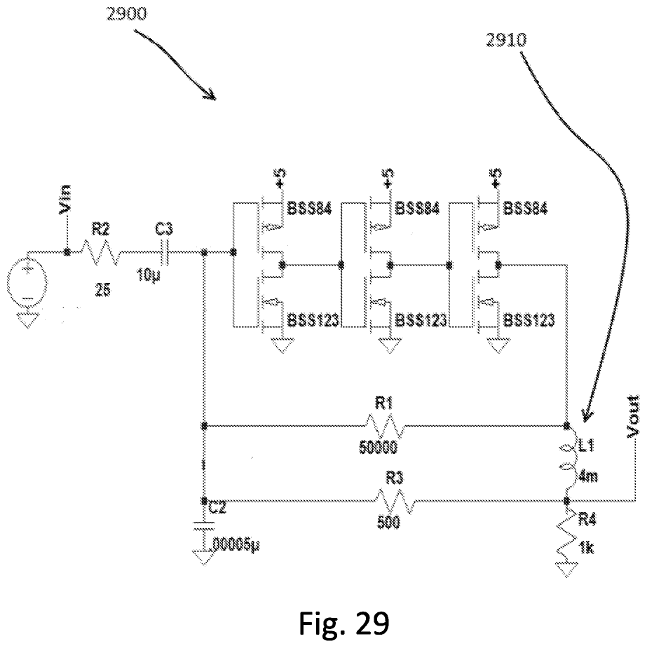

FIG. 29 illustrates an inverting amplifier 2900 based circuit wherein L1 2910 is used for a low-pass filter component and delay rather than a capacitor.

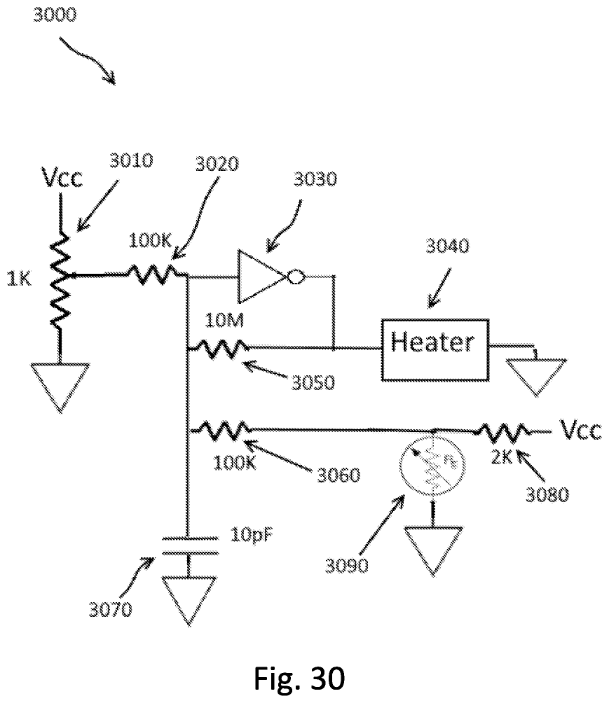

FIG. 30 illustrates a PID controller 3000 using an inverting amplifier 3030 in a temperature control application to control a load, such as a heater 3040. Potentiometer 3010 adjusts the set point. Capacitor 3070 is 10 picofarads. Resistor 3020 is 100 K ohms. Resistor 3060 is 100 K ohms. Thermistor 3090 measures and controls the temperature of the heater using voltage divider with resistor 3080 which is 2 K ohms. All frequency passing attenuator resistor 3050 is 10 megaohms.

1. A topology configured to calculate a derivative of an input signal, the input signal being an electrical signal, and reintegrate the derivative to generate an output signal with a voltage matching a voltage of the input signal and with a current being equal and opposite to a current of the input signal.

2. The topology of claim 1, comprising a circuit, the circuit at least including:
an inverting amplifier circuit portion being in an electrical connection with a source of an input signal;
a delay circuit portion being in an electrical connection with at least an output from the inverting amplifier circuit portion; and
an output signal attenuation component being in an electrical connection with at least the delay circuit portion;
the circuit configured to generate a derivative of the input signal, amplify the derivative and subsequently convert the input signal into the output signal.

3. The topology of claim 1, comprising a circuit, the circuit at least including:
an input signal attenuation component being in an electrical connection with a source of an input signal;
an inverting amplifier circuit portion being in an electrical connection with a source of an input signal;
a delay circuit portion being in an electrical connection with at least an output from the inverting amplifier circuit portion; and
an output signal attenuation component being in an electrical connection with at least the delay circuit portion;
the circuit configured to generate a derivative of the input signal, amplify the derivative and subsequently convert the input signal into the output signal.

4. The topology of claim 1, comprising at least one processor and a non-transitory machine-readable storage medium that includes instructions that when executed by one or more processors cause the at least one processor to at least:
calculate the derivative of the input signal; and
reintegrate the derivative to generate an output signal.

5. The topology of claim 4, wherein calculating the derivative of the input signal comprises calculating a delay.

6. The topology of claim 4, wherein calculating the derivative of the input signal comprises subtracting a delayed signal from a signal inputted from a signal source.

7. The topology of claim 4, wherein calculating the derivative of the input signal comprises forcing a filtered output of a square wave oscillator to match the input signal.

8. The topology of claim 7, wherein forcing the filtered output comprises subtracting an output signal from the input signal and quantizing an error which is a derivative of the input signal.

9. A circuit configured to calculate a derivative of an input signal, the input signal being an electrical signal, and reintegrate the derivative to generate an output signal with a value of at least one of a current and a voltage being greater than a value of at least one respective one of a current and a voltage of the input signal.

10. The circuit of claim 9, comprising:
a resistor in an electrical connection with a source of an input signal;
a frequency inverter in an electrical serial connection with the resistor;
a resistor divider in an electrical connection with the frequency inverter; and
a resistor-capacitor (RC) filter in an electrical connection with the frequency inverter, the resistor divider and a load;
the circuit configured to convert the input signal from the source into the output signal via first generating a derivative in the input signal and then amplifying the derivative.

11. The circuit of claim 9, comprising:
a frequency inverter in an electrical serial connection with a source of the input signal;
a resistor divider in an electrical connection with the frequency inverter; and
a resistor-capacitor (RC) filter in an electrical connection with the frequency inverter, the resistor divider and a load.

12. The circuit of claim 11, further comprising a resistor in an electrical connection with the source of the input signal and a frequency inverter.

13. The circuit of claim 9, comprising:
an input signal attenuation component being in an electrical connection with a source of the input signal;
an inverting amplifier circuit portion being in an electrical connection with the input signal attenuation component;
a delay circuit portion being in an electrical connection with at least an output from the inverting amplifier circuit portion; and
an output signal attenuation component being in an electrical connection with at least the delay circuit portion.

14. The circuit of claim 9, comprising:
an inverting amplifier circuit portion being in an electrical connection with a source of the input signal;
a delay circuit portion being in an electrical connection with at least an output from the inverting amplifier circuit portion; and
an output signal attenuation component being in an electrical connection with at least the delay circuit portion.

15. The circuit of claim 14, further comprising an input signal attenuation component being in an electrical connection with the inverting amplifier circuit portion.

16. The circuit of claim 9, comprising:
a resistor Rp_ᵢₙ, the Rp_ᵢₙ configured to receive an input signal, wherein the Rp_ᵢₙ connected to a node₁;
a resistor divider;
a logic inverter Logᵢₙᵥ, the Logᵢₙᵥ including a Logᵢₙᵥ input and a Logᵢₙᵥ output, wherein the node₁ is connected to the Logᵢₙᵥ input and the Logᵢₙᵥ output is connected to a node₂;
a resistor-capacitor (RC) filter connected to the node₂ and a ground;
wherein the resistor divider is connected to the node₁ and the node₂;
wherein a virtual ground V_{GND} is formed at the node₁; and
a capacitor C_{aliasing} connected to a center of the resistor divider, V_{GND} and connected to the ground;
the circuit being configured as a negative feedback amplifier circuit.

17. (canceled)

18. (canceled)

19. The circuit of claim 16, wherein an output node configured to generate the output signal and wherein the RC filter is connected to the output node.

20. The circuit of claim 9, comprising:
circuit topology comprising a node₁, a node₂, a node₃, a node₄, and a node₅;
a resistor Rp_ᵢₙ connected to the node₁, the Rp_ᵢₙ configured to receive an input signal,
a resistor divider comprising a resistor Rp_ₐₚ and a resistor Rp_{_lp}, wherein:
the Rp_ₐₚ and the Rp_{_lp} are connected in parallel;
the Rp_ₐₚ is connected to the node₂ and the node₃;
the node₁ is connected to the node₃;
the Rp_{_lp} is connected to the node₄ and the node₅;
a logic inverter Logᵢₙᵥ, the Logᵢₙᵥ including a Logᵢₙᵥ input and a Logᵢₙᵥ output, wherein the node₁ is connected to the Logᵢₙᵥ input and the Logᵢₙᵥ output is connected to the node₂;
a resistor-capacitor (RC) amplifier comprising a resistor Rₗₚ and a capacitor Cₗₚ, Wherein:
the Rₗₚ is connected to the node₂ and the node₅;
the Cₗₚ is connected to the nodes and ground;
a capacitor C_{aliasing} connected to the node₄ and ground.

21. The circuit of claim 20, wherein a resistor divider being configured to form a feedback loop in which the Rp_ₐₚ being configured as an all-pass resistor and the Rp_{_lp} being configured as a low-pass resistor.

22. The circuit of claim 20, wherein a virtual ground V_{GND} is formed at the node₁.

23. The circuit claim 20, wherein V_{GND} is a difference of an input signal and a delayed input signal which is the derivative of the input signal.

24. The circuit of claim 20, wherein the node₅ is configured to generate an output signal.

25. The circuit of claim 20, wherein the circuit is configured to receive an input voltage Vᵢₙ at Rp_ᵢₙ and generate an output voltage at Vₒᵤₜ at nodes; and
[Rp_ₐₚ+Rp_ₗₚ]/Rp_ᵢₙ is selected to produce a voltage gain at Vₒᵤₜ.

26. The circuit of claim 20, wherein Rp_ₐₚ/Rp_{_in} sets a gain of a differential of the input signal for an amplifier circuit; and
Rp_ₗₚ/Rp_ᵢₙ sets the gain of the input signal, an integral of an inverter output.

27. A method, comprising steps of:
calculating a derivative of an input electrical signal; and
reintegrating the derivative to generate an output electrical signal with a voltage matching a voltage of the input electrical signal and with a current being equal and opposite to a current of the input electrical signal.

28-33. (canceled)

34. The method of claim 27, wherein the step of reintegrating the derivative comprises a step of encoding the derivative into a timing of a sigma delta square wave and a step of applying the sigma delta square wave to a resistor-capacitor (RC) filter.
